(19) United States
(12) Patent Application Publication
(10) Pub. No.: US 2024/0181560 A1
(43) Pub. Date: Jun. 6, 2024

(54) LASER MACHINING METHOD AND LASER MACHINING DEVICE

(71) Applicant: HAMAMATSU PHOTONICS K.K., Hamamatsu-shi, Shizuoka (JP)

(72) Inventors: Takeshi SAKAMOTO, Hamamatsu-shi, Shizuoka (JP); Yo SUGIMOTO, Hamamatsu-shi, Shizuoka (JP)

(73) Assignee: HAMAMATSU PHOTONICS K.K., Hamamatsu-shi, Shizuoka (JP)

(21) Appl. No.: 18/285,520

(22) PCT Filed: Mar. 1, 2022
(86) PCT No.: PCT/JP2022/008694

§ 371 Date: Oct. 4, 2023

(30) Foreign Application Priority Data
Apr. 8, 2021 (JP) 2021-065721

(51) Int. Cl. B23K 26/0622; B23K 26/38

(52) U.S. Cl. CPC B23K 26/0622; B23K 26/38

(57) ABSTRACT

A laser machining method performed by a laser machining device includes: a first step of flattening an irradiation surface through laser annealing by irradiating a surface or a back surface of an object with a laser beam, the object including a functional element layer on a surface side; and a second step of forming a modified layer inside the object by irradiating the irradiation surface, which is flattened in the first step, with a laser beam. A pulse pitch of the laser beam is shorter than a pulse pitch of the laser beam.

### TECHNICAL FIELD

One aspect of the present invention relates to a laser machining method and a laser machining device.

### BACKGROUND ART

In order to cut a wafer including a semiconductor substrate and a functional element layer formed on one surface of the semiconductor substrate, along each of a plurality of lines, a laser machining device that irradiates the wafer with a laser beam from the other surface side of the semiconductor substrate to form a plurality of rows of modified layers inside the semiconductor substrate along each of the plurality of lines has been known (for example, refer to Patent Literature 1).

### CITATION LIST

### Patent Literature

Patent Literature 1: Japanese Unexamined Patent Publication No. 2017-64746

### SUMMARY OF INVENTION

### Technical Problem

Here, when an irradiation surface for a laser beam of an object in which modified layers are formed is not flat but rough, the laser beam may be absorbed or scattered on the irradiation surface, and in this case, the modified layers cannot be appropriately formed inside the object, which is a risk.

One aspect of the present invention has been conceived in view of the foregoing circumstances, and an object of the present invention is to appropriately flatten an irradiation surface of an object and to appropriately form a modified layer inside the object.

### Solution to Problem

According to one aspect of the present invention, there is provided a laser machining method including: a first step of flattening an irradiation surface through laser annealing by irradiating a surface or a back surface of an object with a first laser beam, the object including a functional element layer on a surface side; and a second step of forming a modified layer inside the object by irradiating the irradiation surface, which is flattened in the first step, with a second laser beam. A pulse pitch of the first laser beam is shorter than a pulse pitch of the second laser beam.

In the laser machining method according to one aspect of the present invention, in a stage before irradiation is performed with the second laser beam for forming the modified layer inside the object, the irradiation surface for the second laser beam is irradiated with the first laser beam for flattening the irradiation surface through the laser annealing. In a case where the irradiation surface for the laser beam when the modified layer is formed is rough and not flat, it may not be able to appropriately form the modified layer through the irradiation with the laser beam. In this regard, as in the laser machining method of the present invention, by irradiating the irradiation surface when the modified layer is formed with the first laser beam for flattening the irradiation surface in advance (by performing laser annealing), the irradiation surface that is flattened can be irradiated with the second laser beam, so that the modified layer can be appropriately formed inside the object. In addition, in the laser machining method according to one aspect of the present invention, the pulse pitch of the first laser beam for the laser annealing is shorter than the pulse pitch of the second laser beam for forming the modified layer. In such a manner, by shortening the pulse pitch of the laser beam for the laser annealing (shorter than the pulse pitch of the laser beam for forming the modified layer), a region that is recrystallized and flattened after melting can be continuously formed, and the flattening of the irradiation surface through the laser annealing can be appropriately realized. As described above, according to the laser machining method of the present invention, the irradiation surface of the object can be appropriately flattened, and the modified layer can be appropriately formed inside the object.

In the laser machining method, the first laser beam and the second laser beam may be emitted from a common light source.

According to such a configuration, the configuration related to laser machining can be simplified, and the downsizing of the device configuration can be realized.

In the laser machining method, a frequency of the first laser beam may be higher than a frequency of the second laser beam. In the laser annealing, by performing irradiation with a next laser beam before the irradiation region cools down after the irradiation with the laser beam, heat is accumulated and recrystallization is appropriately performed, so that the flattening of the irradiation surface can be realized. In this regard, by increasing the frequency of the first laser beam (higher than the frequency of the second laser beam), the flattening of the irradiation surface through the laser annealing can be more appropriately realized.

In the laser machining method, the number of branches of the first laser beam in a machining progress direction may be larger than the number of branches of the second laser beam in the machining progress direction. By increasing the number of branches of the first laser beam in the machining progress direction (larger than the number of branches of the second laser beam), the time required for the laser annealing process can be shortened.

In the laser machining method, the number of branches of the first laser beam in a direction intersecting a machining progress direction and parallel to the irradiation surface may be larger than the number of branches of the second laser beam in the direction intersecting the machining progress direction and parallel to the irradiation surface. Accordingly, the width flattened by the laser annealing process can be increased.

In the laser machining method, irradiation ranges of branched beams of the first laser beam may partially overlap each other on the irradiation surface. Accordingly, even when the energy per point is low, flattening can be performed. In addition, with the laser beam, unevenness occurs between the center of the beam and a location away from the center of the beam; however, by performing irradiation with the branched beams such that the irradiation ranges overlap each other, the above-described unevenness can be suppressed, and the irradiation surface can be more appropriately flattened.

In the laser machining method, the first laser beam may be a laser beam having a top-hat shape. Accordingly, a laser annealing region on the irradiation surface can be widened. In addition, the irradiation surface can be more flattened.

In the laser machining method, in the first step, the irradiation surface may be irradiated with the first laser beam such that the irradiation surface is flattened and the modified layer is formed inside the object. In such a manner, by also using the first laser beam for the laser annealing for flattening to form the modified layer, for example, the number of passes of the second laser beam for forming the modified layer is reduced, so that the time required for forming the modified layer can be shortened.

In the laser machining method, in the first step, the irradiation surface may be irradiated with the first laser beam such that the modified layer is not formed inside the object. Accordingly, a situation where a desired modified layer cannot be formed due to the unintended formation of a modified layer by the laser beam for the laser annealing can be avoided.

In the laser machining method, in the first step, a condensing point of the first laser beam may be set to a position outside the object. Accordingly, the formation of the modified layer inside the object by the laser beam for the laser annealing can be appropriately avoided.

In the laser machining method, in the first step, the back surface may be irradiated with the first laser beam using the back surface as the irradiation surface, to flatten the back surface. For example, the back surface of the object may be satin-finished or rough. When the back surface of the object is irradiated with the laser beam for forming the modified layer, the laser beam may be absorbed or scattered on the back surface, so that the modified layer cannot be appropriately formed inside the object. In this regard, the back surface is irradiated with the laser beam for the laser annealing using the back surface as the irradiation surface, to appropriately flatten the back surface that is rough, so that the modified layer can be appropriately formed inside the object.

The laser machining method may further include a first grooving step of forming a weakened region on the surface by performing irradiation with a third laser beam from the back surface of the object before the second step. In the first step, the back surface before the first grooving step may be irradiated with the first laser beam using the back surface as the irradiation surface, to flatten the back surface. After the weakened region is formed on the surface including the functional element layer in the first grooving step, by irradiating the back surface with the second laser beam for forming the modified layer in the second step, a crack reaching the surface side on which the functional element layer is formed can be appropriately formed using the weakened region. Here, when the first grooving step is performed, if there is a damage to the back surface on which the third laser beam is incident, it is difficult to appropriately perform grooving (IR grooving) on the surface side, and the energy of the third laser beam for the grooving is limited. In this regard, by performing the first step for the laser annealing using the back surface as the irradiation surface before the first grooving step, the first grooving step is performed in a state where the back surface is flattened, so that the energy that can be input to the third laser beam in the first grooving step increases and the types of the objects (devices) that can be handled increase. Accordingly, the grooving (IR grooving) can be more easily and appropriately performed on the surface side.

The laser machining method may further include a second grooving step of removing a surface layer of the surface of the object by irradiating the surface with a fourth laser beam. In the first step, a bottom surface of a groove formed on the surface by the second grooving step may be irradiated with the first laser beam using the bottom surface as the irradiation surface, to flatten the bottom surface of the groove. After the surface layer of the surface is removed in the second grooving step, by irradiating the surface with the second laser beam for forming the modified layer in the second step, the machining throughput can be improved, and a reduction in machining quality, such as film peeling, can be suppressed. Here, after the second grooving step, the bottom surface of the groove formed on the surface by the grooving is roughened. For this reason, normally, stealth dicing machining cannot be performed from the surface after the grooving, and a transfer is made to a back surface side and irradiation is performed with the second laser beam for forming the modified layer from the back surface side. In this case, the transfer cost increases, which is a problem. In this regard, after the second grooving step, by performing the first step for the laser annealing using the bottom surface of the groove, which is formed on the surface, as the irradiation surface, the bottom surface of the groove formed on the surface is flattened, so that stealth dicing machining can be performed from the surface that is a grooving surface side, and the above-described transfer step is not required. Accordingly, a speeding up in machining and a reduction in cost can be realized.

According to one aspect of the present invention, there is provided a laser machining device including: a support unit that supports an object including a functional element layer on a surface side; an irradiation unit that irradiates the object with a laser beam; and a control unit configured to perform a first control to control the irradiation unit such that a surface or a back surface of the object is irradiated with a first laser beam to flatten an irradiation surface through laser annealing, and a second control to control the irradiation unit such that the irradiation surface which is flattened is irradiated with a second laser beam having a longer pulse pitch than the first laser beam, to form a modified layer inside the object.

In the laser machining device, in the first control, the control unit may control the irradiation unit such that the back surface is irradiated with the first laser beam using the back surface as the irradiation surface, to flatten the back surface.

In the laser machining device, the control unit may further perform a first grooving control to control the irradiation unit such that irradiation is performed with a third laser beam from the back surface of the object to form a weakened region on the surface, before performing the second control, and in the first control, may control the irradiation unit such that the back surface before the first grooving control is performed is irradiated with the first laser beam using the back surface as the irradiation surface, to flatten the back surface.

In the laser machining device, the control unit may further perform a second grooving control to control the irradiation unit such that the surface of the object is irradiated with a fourth laser beam to remove a surface layer of the surface, and in the first control, may control the irradiation unit such that a bottom surface of a groove formed on the surface by the second grooving control is irradiated with the first laser beam using the bottom surface as the irradiation surface, to flatten the bottom surface of the groove.

### Advantageous Effects of Invention

According to one aspect of the present invention, it is possible to appropriately flatten the irradiation surface of the object and to appropriately form the modified layer inside the object.

### BRIEF DESCRIPTION OF DRAWINGS

FIG. 1 is a perspective view of a laser machining device according to one embodiment.

FIG. 2 is a front view of a portion of the laser machining device shown in FIG. 1.

FIG. 3 is a front view of a laser machining head of the laser machining device shown in FIG. 1.

FIG. 4 is a side view of the laser machining head shown in FIG. 3.

FIG. 5 is a configuration view of an optical system of the laser machining head shown in FIG. 3.

FIG. 6 is a view describing problems during stealth dicing machining.

FIG. 7 is a view describing problems during stealth dicing machining.

FIG. 8 is a view describing a flattening process and a modified layer forming process after the flattening process.

FIG. 9 is a table showing experimental results related to conditions of laser beams.

FIG. 10 is a view showing laser annealing results for each condition of the laser beams shown in FIG. 9.

FIG. 11 is a view describing an improvement in flatness by horizontal branching.

FIG. 12 is a view describing a reduction in tact time and an increase in flattening width by horizontal branching.

FIG. 13 is a view describing the effect of branching in a direction intersecting a machining progress direction.

FIG. 14 is a view showing one example of laser annealing and the formation of a modified layer for each condensing position.

FIG. 15 is a view showing one example of a GUI.

FIG. 16 is a view showing one example of the GUI.

FIG. 17 is a flowchart showing a laser machining method including the flattening process and the modified layer forming process.

FIG. 18 is a view describing the flattening process and IR grooving and the modified layer forming process after the flattening process.

FIG. 19 is a flowchart showing a laser machining method including the flattening process, the IR grooving, and the modified layer forming process.

FIG. 20 is a view schematically showing one example of the flattening process and the IR grooving and the modified layer forming process after the flattening process.

FIG. 21 is a view describing laser grooving and the flattening process and the modified layer forming process after the laser grooving.

FIG. 22 is a flowchart showing a laser machining method including the laser grooving, the flattening process, and the modified layer forming process.

FIG. 23 is a view schematically showing one example of the laser grooving and the flattening process and the modified layer forming process after the laser grooving.

### DESCRIPTION OF EMBODIMENTS

Hereinafter, an embodiment of the present invention will be

described in detail with reference to the drawings. Incidentally, in the drawings, the same or corresponding portions will be denoted by the same reference signs, and duplicate descriptions will be omitted.

### [Configuration of Laser Machining Device]

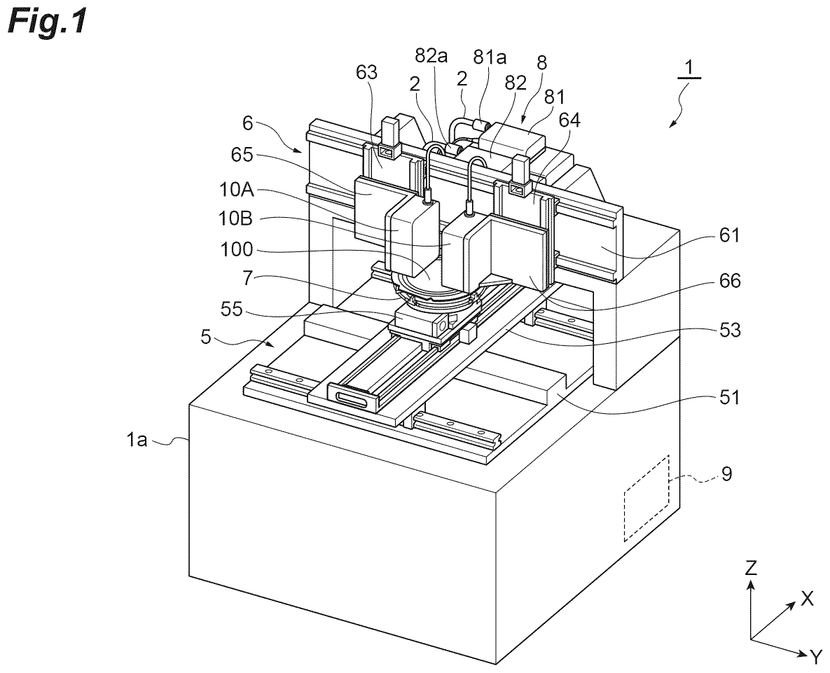

As shown in FIG. 1, a laser machining device 1 performs a laser machining method according to an embodiment. The laser machining device 1 includes a plurality of movement mechanisms 5 and 6, a support unit 7, a pair of laser machining heads 10A and 10B, a light source unit 8, and a control unit 9. Hereinafter, a first direction is referred to as an X direction, a second direction perpendicular to the first direction is referred to as a Y direction, and a third direction perpendicular to the first direction and the second direction is referred to as a Z direction. In the present embodiment, the X direction and the Y direction are horizontal directions, and the Z direction is a vertical direction.

The movement mechanism 5 includes a fixed portion 51, a moving portion 53, and an attachment portion 55. The fixed portion 51 is attached to a device frame 1a. The moving portion 53 is attached to rails provided on the fixed portion 51, and is movable along the Y direction. The attachment portion 55 is attached to rails provided on the moving portion 53, and is movable along the X direction.

The movement mechanism 6 includes a fixed portion 61, a pair of moving portions 63 and 64, and a pair of attachment portions 65 and 66. The fixed portion 61 is attached to the device frame 1a. Each of the pair of moving portions 63 and 64 is attached to rails provided on the fixed portion 61, and is independently movable along the Y direction. The attachment portion 65 is attached to rails provided on the moving portion 63, and is movable along the Z direction. The attachment portion 66 is attached to rails provided on the moving portion 64, and is movable along the Z direction. Namely, each of the pair of attachment portions 65 and 66 is movable along each of the Y direction and the Z direction with respect to the device frame 1a.

The support unit 7 is attached to a rotating shaft provided on the attachment portion 55 of the movement mechanism 5, and is rotatable around an axis parallel to the Z direction. Namely, the support unit 7 is movable along each of the X direction and the Y direction, and is rotatable around the axis parallel to the Z direction. The support unit 7 supports an object 100. The object 100 is a wafer. The object 100 includes a semiconductor substrate and a plurality of functional elements (functional element layer). The semiconductor substrate is, for example, a silicon substrate. For example, the functional elements are two-dimensionally disposed along a surface of the semiconductor substrate. Each of the functional elements is, for example, a light-receiving element such as a photodiode, a light-emitting element such as a laser diode, a circuit element such as a memory, or the like. The functional elements may be three-dimensionally configured by being stacked in a plurality of layers.

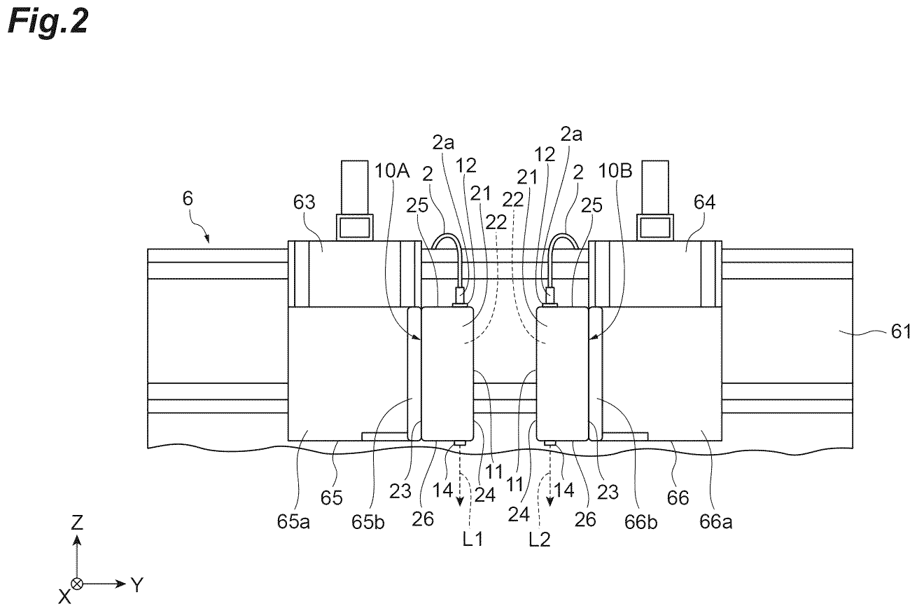

As shown in FIGS. 1 and 2, the laser machining head 10A is attached to the attachment portion 65 of the movement mechanism 6. The laser machining head 10A irradiates the object 100 supported by the support unit 7, with a laser beam L1 (first laser beam) in a state where the laser machining head 10A faces the support unit 7 in the Z direction. The laser machining head 10B is attached to the attachment portion 66 of the movement mechanism 6. The laser machining head 10B irradiates the object 100 supported by the support unit 7, with a laser beam L2 (second laser beam) in a state where the laser machining head 10B faces the support unit 7 in the Z direction.

The light source unit 8 includes a pair of light sources 81 and 82. The light source 81 outputs the laser beam L1. The laser beam L1 is emitted from an emitting unit 81a of the light source 81, and is guided to the laser machining head 10A by an optical fiber 2. The light source 82 outputs the laser beam L2. The laser beam L2 is emitted from an emitting unit 82a of the light source 82, and is guided to the laser machining head 10B by another optical fiber 2.

The control unit 9 controls each part (the plurality of movement mechanisms 5 and 6, the pair of laser machining heads 10A and 10B, the light source unit 8, and the like) of the laser machining device 1. The control unit 9 is configured as a computer device including a processor, a memory, a storage, a communication device, and the like. In the control unit 9, software (program) read into the memory or the like is executed by the processor, and the reading and writing of data in the memory and the storage and communication through the communication device are controlled by the processor. Accordingly, the control unit 9 realizes various functions.

### [Configuration of Laser Machining Head]

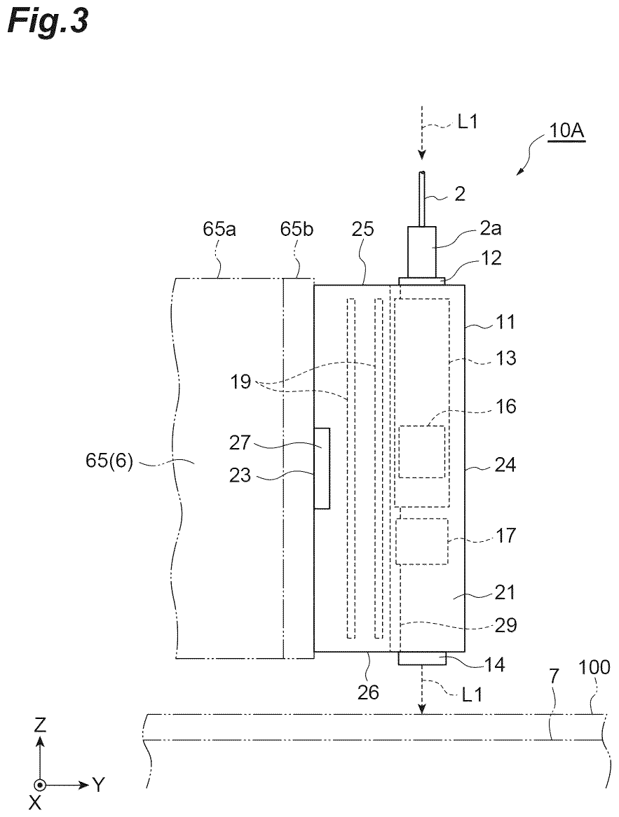

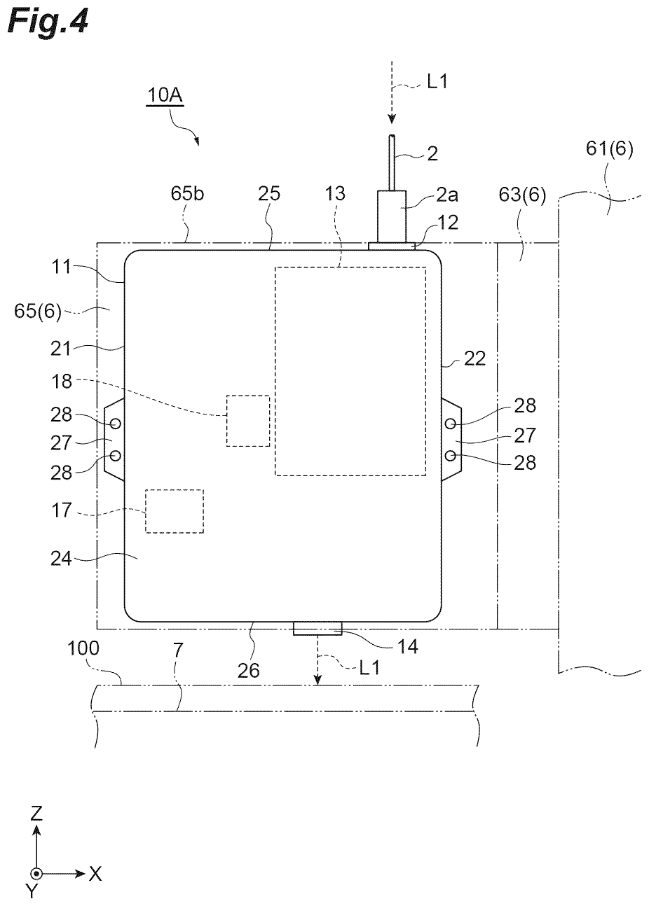

As shown in FIGS. 3 and 4, the laser machining head 10A includes a housing 11, an incident unit 12, an adjustment unit 13, and a condensing unit 14.

The housing 11 includes a first wall portion 21, a second wall portion 22, a third wall portion 23, a fourth wall portion 24, a fifth wall portion 25, and a sixth wall portion 26. The first wall portion 21 and the second wall portion 22 face each other in the X direction. The third wall portion 23 and the fourth wall portion 24 face each other in the Y direction. The fifth wall portion 25 and the sixth wall portion 26 face each other in the Z direction.

A distance between the third wall portion 23 and the fourth wall portion 24 is smaller than a distance between the first wall portion 21 and the second wall portion 22. The distance between the first wall portion 21 and the second wall portion 22 is smaller than a distance between the fifth wall portion 25 and the sixth wall portion 26. Incidentally, the distance between the first wall portion 21 and the second wall portion 22 may be equal to the distance between the fifth wall portion 25 and the sixth wall portion 26, or may be larger than the distance between the fifth wall portion 25 and the sixth wall portion 26.

In the laser machining head 10A, the first wall portion 21 is located on a fixed portion 61 side of the movement mechanism 6, and the second wall portion 22 is located opposite to the fixed portion 61. The third wall portion 23 is located on an attachment portion 65 side of the movement mechanism 6, and the fourth wall portion 24 is located opposite to the attachment portion 65 and on a laser machining head 10B side (refer to FIG. 2). The fifth wall portion 25 is located opposite to the support unit 7, and the sixth wall portion 26 is located on a support unit 7 side.

The housing 11 is configured such that the housing 11 is attached to the attachment portion 65 in a state where the third wall portion 23 is disposed on the attachment portion 65 side of the movement mechanism 6. Specifically, the configuration is as follows. The attachment portion 65 includes a base plate 65a and an attachment plate 65b. The base plate 65a is attached to the rails provided on the moving portion 63 (refer to FIG. 2). The attachment plate 65b is erected at an end portion on the laser machining head 10B side of the base plate 65a (refer to FIG. 2). The housing 11 is attached to the attachment portion 65 by screwing a bolt 28 into the attachment plate 65b through pedestals 27 in a state where the third wall portion 23 is in contact with the attachment plate 65b. The pedestal 27 is provided on each of the first wall portion 21 and the second wall portion 22. The housing 11 is attachable and detachable from the attachment portion 65.

The incident unit 12 is attached to the fifth wall portion 25. The incident unit 12 allows the laser beam L1 to be incident on the housing 11. The incident unit 12 is biased toward a second wall portion 22 side (one wall portion side) in the X direction, and is biased toward a fourth wall portion 24 side in the Y direction. Namely, a distance between the incident unit 12 and the second wall portion 22 in the X direction is smaller than a distance between the incident unit 12 and the first wall portion 21 in the X direction, and a distance between the incident unit 12 and the fourth wall portion 24 in the Y direction is smaller than a distance between the incident unit 12 and the third wall portion 23 in the X direction.

The incident unit 12 is configured such that a connection end portion 2a of the optical fiber 2 can be connected to the incident unit 12. At the connection end portion 2a of the optical fiber 2, a collimator lens that collimates the laser beam L1 emitted from an emitting end of the fiber is provided and an isolator that suppresses return light is not provided. The isolator is provided in the middle of the fiber closer to a light source 81 side than to the connection end portion 2a. Accordingly, the downsizing of the connection end portion 2a or the downsizing of the incident unit 12 is achieved. Incidentally, the isolator may be provided at the connection end portion 2a of the optical fiber 2.

The adjustment unit 13 is disposed inside the housing 11. The adjustment unit 13 adjusts the laser beam L1 incident from the incident unit 12. Each configuration included in the adjustment unit 13 is attached to an optical base 29 provided inside the housing 11. The optical base 29 is attached to the housing 11 so as to partition a region inside the housing 11 into a region on a third wall portion 23 side and a region on the fourth wall portion 24 side. The optical base 29 is integrated with the housing 11. Details of each configuration included in the adjustment unit 13, which is attached to the optical base 29 on the fourth wall portion 24 side, will be described later.

The condensing unit 14 is disposed on the sixth wall portion 26. Specifically, the condensing unit 14 is disposed on the sixth wall portion 26 in a state where the condensing unit 14 is inserted into a hole 26a formed in the sixth wall portion 26. The condensing unit 14 emits the laser beam L1 adjusted by the adjustment unit 13, to the outside of the housing 11 while condensing the laser beam L1. The condensing unit 14 is biased toward to the second wall portion 22 side (one wall portion side) in the X direction, and is biased toward the fourth wall portion 24 side in the Y direction. Namely, a distance between the condensing unit 14 and the second wall portion 22 in the X direction is smaller than a distance between the condensing unit 14 and the first wall portion 21 in the X direction, and a distance between the condensing unit 14 and the fourth wall portion 24 in the Y direction is smaller than a distance between the condensing unit 14 and the third wall portion 23 in the X direction.

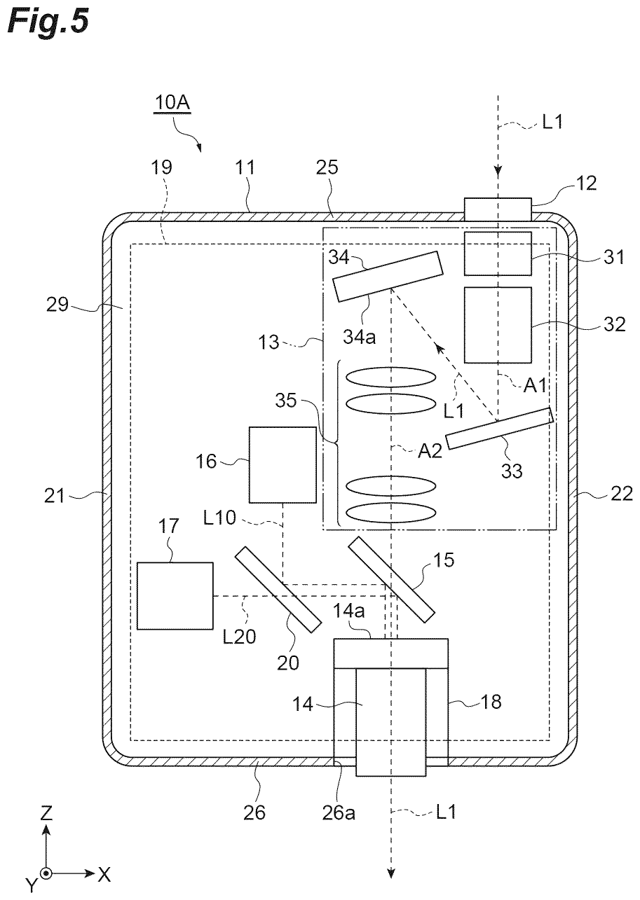

As shown in FIG. 5, the adjustment unit 13 includes an attenuator 31, a beam expander 32, and a mirror 33. The incident unit 12 and the attenuator 31, the beam expander 32, and the mirror 33 of the adjustment unit 13 are disposed on a straight line (first straight line) A1 extending along the Z direction. The attenuator 31 and the beam expander 32 are disposed between the incident unit 12 and the mirror 33 on the straight line A1. The attenuator 31 adjusts the output of the laser beam L1 incident from the incident unit 12. The beam expander 32 increases the diameter of the laser beam L1 of which the output is adjusted by the attenuator 31. The mirror 33 reflects the laser beam L1 of which the diameter is increased by the beam expander 32.

The adjustment unit 13 further includes a reflective spatial light modulator 34 and an image-forming optical system 35. The reflective spatial light modulator 34 and the image-forming optical system 35 of the adjustment unit 13 and the condensing unit 14 are disposed on a straight line (second straight line) A2 extending along the Z direction. The reflective spatial light modulator 34 modulates the laser beam L1 reflected by the mirror 33. The reflective spatial light modulator 34 is, for example, a reflective liquid crystal on silicon (LCOS)-spatial light modulator (SLM). The image-forming optical system 35 constitutes a double-sided telecentric optical system in which a reflective surface 34a of the reflective spatial light modulator 34 and an entrance pupil surface 14a of the condensing unit 14 are in an image-forming relationship. The image-forming optical system 35 is composed of three or more lenses.

The straight line A1 and the straight line A2 are located on a plane perpendicular to the Y direction. The straight line A1 is located on the second wall portion 22 side (one wall portion side) with respect to the straight line A2. In the laser machining head 10A, the laser beam L1 is incident on the housing 11 from the incident unit 12, travels on the straight line A1, is sequentially reflected by the mirror 33 and the reflective spatial light modulator 34, and then travels on the straight line A2, and is emitted from the condensing unit 14 to the outside of the housing 11. Incidentally, the order of arrangement of the attenuator 31 and the beam expander 32 may be reversed. In addition, the attenuator 31 may be disposed between the mirror 33 and the reflective spatial light modulator 34. In addition, the adjustment unit 13 may include other optical components (for example, a steering mirror disposed in front of the beam expander 32, and the like).

The laser machining head 10A further includes a dichroic mirror 15, a measurement unit 16, an observation unit 17, a drive unit 18, and a circuit unit 19.

The dichroic mirror 15 is disposed between the image-forming optical system 35 and the condensing unit 14 on the straight line A2. Namely, the dichroic mirror 15 is disposed between the adjustment unit 13 and the condensing unit 14 inside the housing 11. The dichroic mirror 15 is attached to the optical base 29 on the fourth wall portion 24 side. The dichroic mirror 15 transmits the laser beam L1. From the viewpoint of suppressing astigmatism, it is preferable that the dichroic mirror 15 is, for example, a cube type or a two-plate type in which two plates are disposed to have a twisted relationship.

The measurement unit 16 is disposed on a first wall portion 21 side (side opposite to the one wall portion side) with respect to the adjustment unit 13 inside the housing 11. The measurement unit 16 is attached to the optical base 29 on the fourth wall portion 24 side. The measurement unit 16 outputs measurement light L10 for measuring a distance between a surface of the object 100 (for example, a surface on a side on which the laser beam L1 is incident) and the condensing unit 14, and detects the measurement light L10 passed through the condensing unit 14 and reflected by the surface of the object 100. Namely, the surface of the object 100 is irradiated with the measurement light L10 output from the measurement unit 16, through the condensing unit 14, and the measurement light L10 reflected by the surface of the object 100 is detected by the measurement unit 16, through the condensing unit 14.

More specifically, the measurement light L10 output from the measurement unit 16 is sequentially reflected by a beam splitter 20 and the dichroic mirror 15 attached to the optical base 29 on the fourth wall portion 24 side, and is emitted from the condensing unit 14 to the outside of the housing 11. The measurement light L10 reflected by the surface of the object 100 is incident on the housing 11 from the condensing unit 14, is sequentially reflected by the dichroic mirror 15 and the beam splitter 20, is incident on the measurement unit 16, and is detected by the measurement unit 16.

The observation unit 17 is disposed on the first wall portion 21 side (side opposite to the one wall portion side) with respect to the adjustment unit 13 inside the housing 11. The observation unit 17 is attached to the optical base 29 on the fourth wall portion 24 side. The observation unit 17 outputs observation light L20 for observing the surface of the object 100 (for example, the surface on the side on which the laser beam L1 is incident), and detects the observation light L20 passed through the condensing unit 14 and reflected by the surface of the object 100. Namely, the surface of the object 100 is irradiated with the observation light L20 output from the observation unit 17, through the condensing unit 14, and the observation light L20 reflected by the surface of the object 100 is detected by the observation unit 17, through the condensing unit 14.

More specifically, the observation light L20 output from the observation unit 17 transmits through the beam splitter 20, is reflected by the dichroic mirror 15, and is emitted from the condensing unit 14 to the outside of the housing 11. The observation light L20 reflected by the surface of the object 100 is incident on the housing 11 from the condensing unit 14, is reflected by the dichroic mirror 15, transmits through the beam splitter 20, is incident on the observation unit 17, and is detected by the observation unit 17. Incidentally, the wavelengths of the laser beam L1, the measurement light L10, and the observation light L20 are different from each other (at least the center wavelengths thereof are shifted from each other).

The drive unit 18 is attached to the optical base 29 on the fourth wall portion 24 side. The drive unit 18 is attached to the sixth wall portion 26 of the housing 11. The drive unit 18 moves the condensing unit 14 disposed on the sixth wall portion 26 along the Z direction, for example, using the driving force of a piezoelectric element.

The circuit unit 19 is disposed on the third wall portion 23 side with respect to the optical base 29 inside the housing 11. Namely, the circuit unit 19 is disposed on the third wall portion 23 side with respect to the adjustment unit 13, the measurement unit 16, and the observation unit 17 inside the housing 11. The circuit unit 19 is, for example, a plurality of circuit substrates. The circuit unit 19 processes a signal output from the measurement unit 16 and a signal input to the reflective spatial light modulator 34. The circuit unit 19 controls the drive unit 18 based on the signal output from the measurement unit 16. As one example, the circuit unit 19 controls the drive unit 18 such that the distance between the surface of the object 100 and the condensing unit 14 is maintained constant (namely, such that the distance between the surface of the object 100 and the condensing point of the laser beam L1 is maintained constant), based on the signal output from the measurement unit 16. Incidentally, the housing 11 is provided with a connector (not shown) to which wirings for electrically connecting the circuit unit 19 to the control unit 9 (refer to FIG. 1) and the like are connected.

Similarly to the laser machining head 10A, the laser machining head 10B includes the housing 11, the incident unit 12, the adjustment unit 13, the condensing unit 14, the dichroic mirror 15, the measurement unit 16, the observation unit 17, the drive unit 18, and the circuit unit 19. However, as shown in FIG. 2, each configuration of the laser machining head 10B is disposed to have a symmetrical relationship with each configuration of the laser machining head 10A with respect to an imaginary plane passing through a middle point between the pair of attachment portions 65 and 66 and perpendicular to the Y direction.

For example, the housing (first housing) 11 of the laser machining head 10A is attached to the attachment portion 65 such that the fourth wall portion 24 is located on the laser machining head 10B side with respect to the third wall portion 23 and the sixth wall portion 26 is located on the support unit 7 side with respect to the fifth wall portion 25. On the other hand, the housing (second housing) 11 of the laser machining head 10B is attached to the attachment portion 66 such that the fourth wall portion 24 is located on a laser machining head 10A side with respect to the third wall portion 23 and the sixth wall portion 26 is located on the support unit 7 side with respect to the fifth wall portion 25.

The housing 11 of the laser machining head 10B is configured such that the housing 11 is attached to the attachment portion 66 in a state where the third wall portion 23 is disposed on an attachment portion 66 side. Specifically, the configuration is as follows. The attachment portion 66 includes a base plate 66a and an attachment plate 66b. The base plate 66a is attached to the rails provided on the moving portion 63. The attachment plate 66b is erected at an end portion on the laser machining head 10A side of the base plate 66a. The housing 11 of the laser machining head 10B is attached to the attachment portion 66 in a state where the third wall portion 23 is in contact with the attachment plate 66b. The housing 11 of the laser machining head 10B is attachable and detachable from the attachment portion 66.

### One Example of Machining by Laser Machining Device (Stealth Dicing)

Next, one example of machining of the object 100 by the laser machining device 1 will be described. Here, an example in which the laser machining device 1 performs stealth dicing machining on the object 100 will be described.

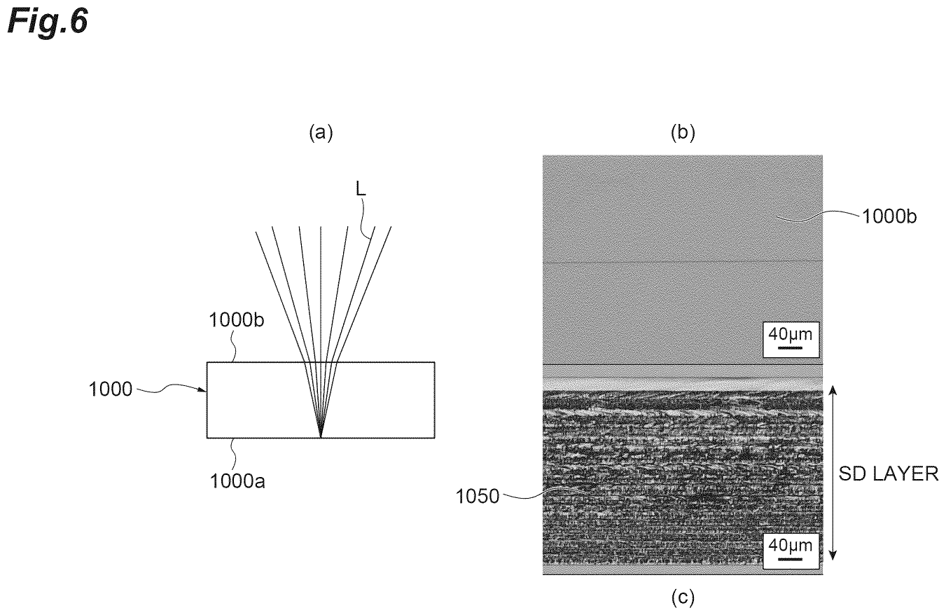

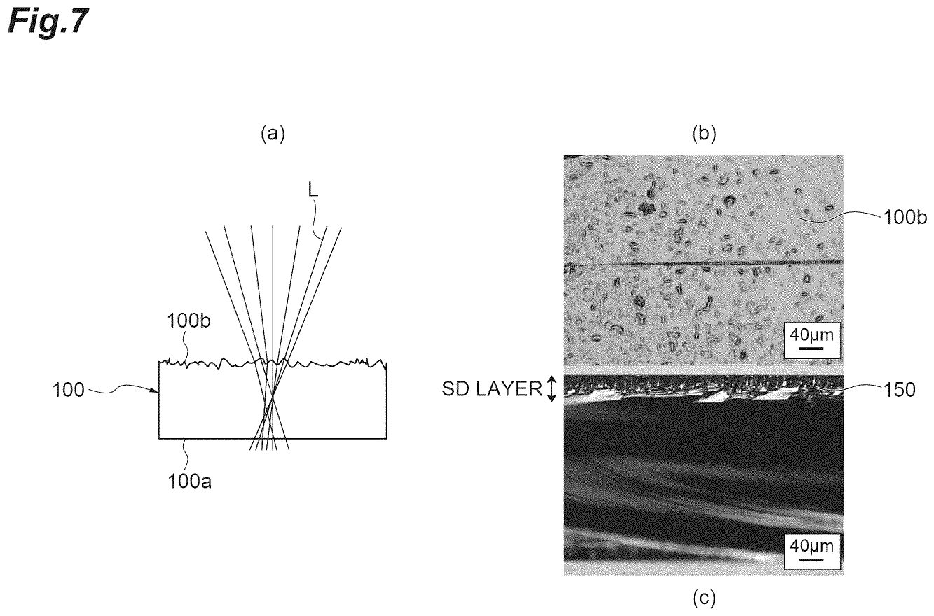

First, problems during stealth dicing machining will be described. FIGS. 6 and 7 are views describing the problems during stealth dicing machining. FIG. 6(a) schematically shows a mode in which an object 1000 having a mirror surface is irradiated with a laser beam L to form a modified layer inside the object 1000. FIG. 6(b) shows a back surface 1000b that is an incident surface (irradiation surface) for the laser beam L. FIG. 6(c) shows a cross section of the object 1000. The object 1000 is a wafer and has the back surface 1000b serving as an incident surface for the laser beam L, and a surface 1000a on which functional elements are formed. In the example shown in FIG. 6(a), the back surface 1000b of the object 1000 which is the incident surface for the laser beam L is a mirror surface (refer to FIG. 6(b)). When the object 1000 is irradiated with the laser beam L, as shown in FIG. 6(c), a modified layer 1050 (SD layer) is appropriately formed inside the object 1000.

FIG. 7(a) schematically shows a mode in which the object 100 of which a back surface 100b is rough is irradiated with the laser beam L to form a modified layer inside the object 100. FIG. 7(b) shows the back surface 100b that is an incident surface (irradiation surface) for the laser beam L. FIG. 7(c) shows a cross section of the object 100. The object 100 is a wafer and has the back surface 100b serving as an incident surface for the laser beam L, and a surface 100a on which the functional elements are formed. In the example shown in FIG. 7(a), the back surface 100b of the object 100 which is the incident surface for the laser beam L is a rough surface with unevenness (rough surface) (refer to FIG. 7(b)). The back surface 100b that is rough refers to, for example, the back surface 100b with an arithmetic mean roughness Ra>0.02 μm. Examples of the object 100 having the back surface 100b that is rough include a wafer in which the back surface 100b is satin-finished (for example, a wafer equal to or less than a predetermined size such as 8 inches), and a wafer that is not sufficiently ground. When the object 100 is irradiated with the laser beam L, as shown in FIG. 7(a), unintended scattering or the like of the laser beam L occurs on the incident surface (irradiation surface), and a modified layer cannot be appropriately formed inside the object 100, which is a risk. For example, as shown in FIG. 7(c), the region of a modified layer 150 cannot be sufficiently formed inside the object 100, which is a risk. In order to avoid such a situation, for example, it can be considered that the wafer is sufficiently ground, but the cost required for grinding increases, which is a problem.

In order to solve such a problem, in the laser machining method performed by the laser machining device 1 according to the present embodiment, before a modified layer forming process for forming a modified layer inside the object 100 by irradiating the back surface 100b with the laser beam L, a flattening process is performed on the back surface 100b, which is the incident surface for the laser beam L, through laser annealing. Laser annealing is a technique for performing material modification such as melting and recrystallization on the irradiation surface by irradiating the irradiation surface with the laser beam. In the laser machining method according to the present embodiment, the irradiation surface is recrystallized and flattened by laser annealing. Accordingly, since the back surface 100b that is flattened is irradiated with the laser beam L for forming a modified layer, the above-described problem is solved and a modified layer is appropriately formed inside the object 100. Namely, a modified layer can be appropriately formed inside the object 100 by performing the modified layer forming process after the flattening process.

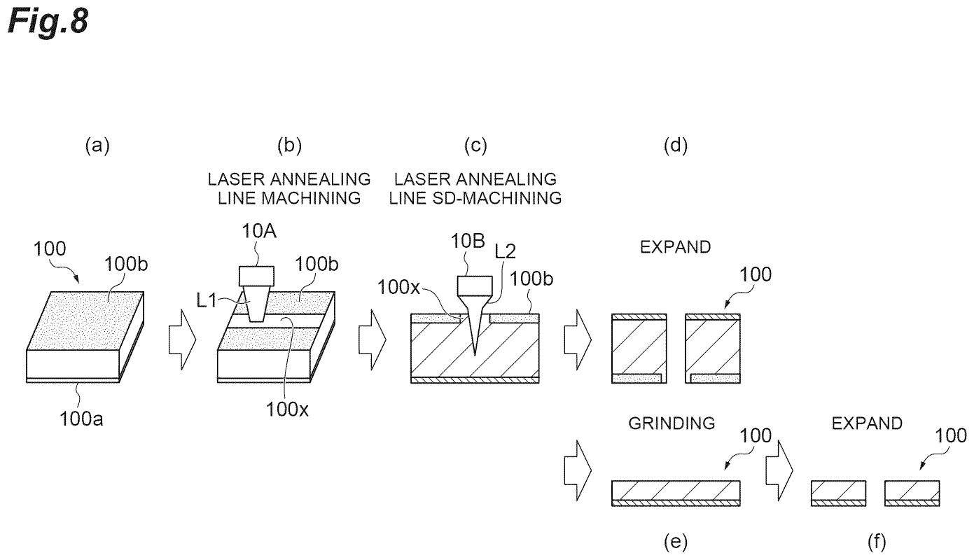

FIG. 8 is a view describing the flattening process and the modified layer forming process after the flattening process. Stealth dicing machining for forming a modified layer is performed to cut the object 100, which is a wafer, into a plurality of chips. Here, it is assumed that the light source 81 outputs the laser beam L1 for laser annealing and the laser machining head 10A irradiates the object 100 with the laser beam L1. In addition, it is assumed that the light source 82 outputs the laser beam L2 for forming a modified layer, and the laser machining head 10B irradiates the object 100 with the laser beam L2. The light source 81 is, for example, a light source that emits an ultrashort pulse laser. The light source 82 is, for example, a light source that emits a nanosecond pulse laser. A pulse pitch of the laser beam L1 for laser annealing emitted from the light source 81 is shorter than at least a pulse pitch of the laser beam L2 for forming a modified layer emitted from the light source 82 (details will be described later). In such a manner, by separately mounting the light source 81 and the laser machining head 10A for the laser beam L1 used in the flattening process and the light source 82 and the laser machining head 10B for the laser beam L2 used in the modified layer forming process, follow-up machining can be performed with laser for the modified layer forming process after the flattening process. Further, a laser dicer for the flattening process and a laser dicer for the modified layer forming process may be provided as two separate devices. In this case, since the two devices can be mounted in parallel to perform the processes, the tact time can be reduced. Incidentally, in this mode, the laser beam L1 and the laser beam L2 may be emitted from the common light source 82. Namely, the laser beam L1 and the laser beam L2 may be the same type of laser (for example, a transmissive laser emitted from the light source 82 that emits a nanosecond pulse laser). In addition, in this mode, irradiation may be performed with the laser beam L1 and the laser beam L2 from a common laser machining head.

First, as shown in FIG. 8(a), the object 100 is prepared, and the object 100 is supported by the support unit 7 (refer to FIG. 1). As shown in FIG. 8(a), the object 100 has the back surface 100b serving as an incident surface for the laser beam L, and the surface 100a on which the functional elements are formed. Subsequently, as shown in FIG. 8(b), the movement mechanism 6 controlled by the control unit 9 moves the laser machining head 10A such that the condensing points of the laser beam L1 are located along one line extending in one direction on the back surface 100b, and the light source 81 controlled by the control unit 9 outputs the laser beam L1 for laser annealing. Namely, the control unit 9 performs a first control to control the light source 81 and the movement mechanism 6 such that the back surface 100b of the object 100 is irradiated with the laser beam L1 to flatten the back surface 100b, which is an irradiation surface, through laser annealing. The first control is control related to a first step (flattening process) of flattening the back surface 100b through laser annealing by irradiating the back surface 100b with the laser beam L1. In the first step, the back surface 100b is irradiated with the laser beam L1 using the back surface 100b as an irradiation surface, to flatten the back surface 100b. Accordingly, the above-described one line becomes a laser annealing line 100x on which laser annealing is performed. The laser annealing line 100x includes at least a dicing line to be irradiated with the laser beam L2 for forming a modified layer, which will be described later. Incidentally, the flattening process may be performed on rough regions (for example, dicing streets roughened by etching) of the surface 100a on a device surface side.

Subsequently, as shown in FIG. 8(c), the movement mechanism 6 controlled by the control unit 9 moves the laser machining head 10B such that the condensing points of the laser beam L2 are located along the laser annealing line 100x described above, and the light source 82 controlled by the control unit 9 outputs the laser beam L2 for forming a modified layer. Namely, the control unit 9 performs a second control to control the light source 82 and the movement mechanism 6 such that the back surface 100b (irradiation surface) which is flattened is irradiated with the laser beam L2 to form a modified layer inside the object 100. The second control is control related to a second step (modified layer forming process) of forming a modified layer inside the object 100 by irradiating the back surface 100b, which is flattened in the first step, with the laser beam L2. After the modified layer is formed in such a manner, an expanding process (FIG. 8(d)) is performed in a dividing step to cut the object 100 into a plurality of chips. Incidentally, after the modified layer is formed, a grinding process (refer to FIG. 8(e)) may be performed, and then the expanding process (FIG. 8(f)) may be performed.

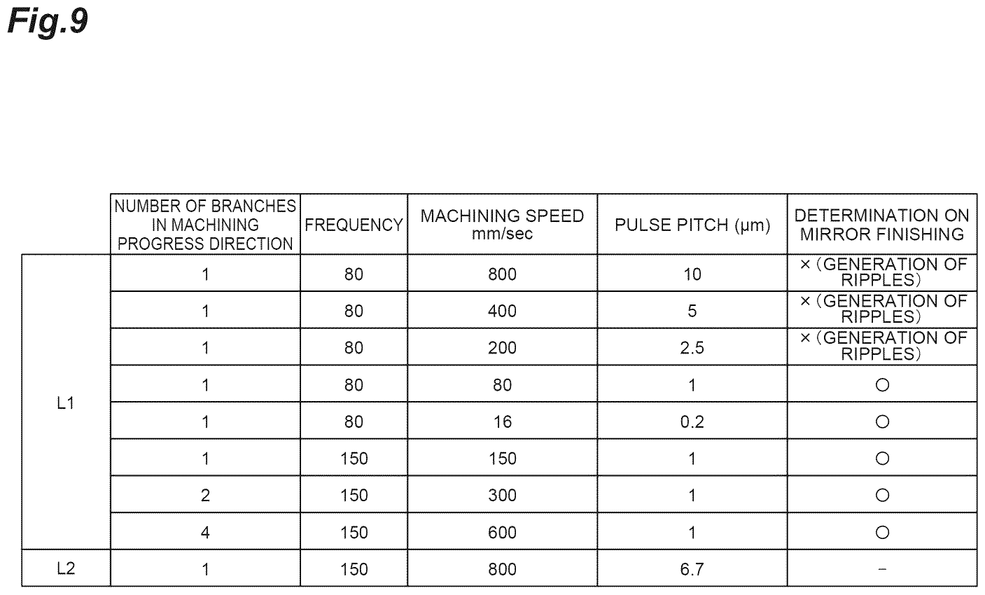

Here, conditions of the laser beam L1 for the flattening process and the laser beam L2 for the modified layer forming process will be described with reference to experimental results shown in FIG. 9. As described above, the laser beam L1 and the laser beam L2 may be the same type of laser emitted from a common light source. FIG. 9 shows the results of determining whether or not the flattening process is appropriately performed through laser annealing, while changing the conditions of the laser beam L1 in a case where the laser beam L1 and the laser beam L2 of the same type are emitted from a common light source (for example, the light source 82).

The experiment was performed on the object 100 that is a silicon wafer with a wafer thickness of 300 μm (crystal orientation <100>) and that has a grinding number of 2000. The wavelength, pulse width, and energy of the laser beam L1 and the laser beam L2 were set to 1099 nm, 700 nsec, and 90 μJ in common, respectively. In addition, as shown in FIG. 9, the number of branches of the laser beam L2 in a machining progress direction was set to 1, the frequency was set to 120 kHz, the machining speed was set to 800 mm/sec, and the pulse pitch was set to 6.7 μm. Such machining conditions of the laser beam L2 are conditions for forming a desired modified layer in the object 100. Then, as shown in FIG. 9, it was determined whether or not the flattening process by the laser beam L1 is appropriately performed, while changing each condition of the number of branches of the laser beam L1 in the machining progress direction, the frequency, the machining speed, and the pulse pitch. In this experiment, a determination was performed on the mirror finishing of the back surface 100b of the object 100 after laser annealing, and when mirror finishing was attained, it was determined that the flattening process was appropriately performed, and when mirror finishing was not attained, it was determined that the flattening process was not appropriately performed.

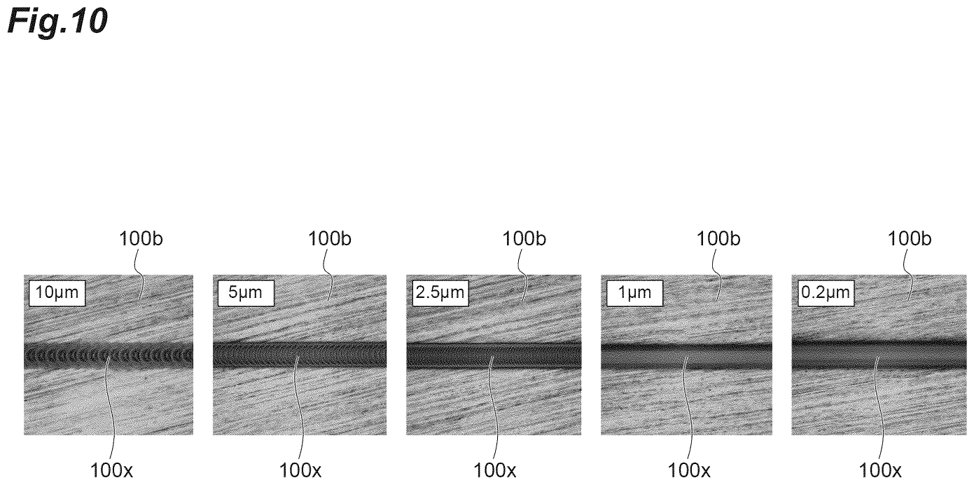

As shown in FIG. 9, when the number of branches of the laser beam L1 in the machining progress direction was set to 1, the frequency was set to 80 kHz, and the pulse pitch was set to 10 μm, 5 μm, 2.5 μm, 1 μm, and 0.2 μm while changing the machining speed, the mirror finishing was determined not to be acceptable for the laser beam L1 with pulse pitches of 10 μm, 5 μm, and 2.5 μm. On the other hand, the mirror finishing was determined to be acceptable for the laser beam L1 with pulse pitches of 1 μm and 0.2 μm. FIG. 10 is a view showing laser annealing results of each laser beam L1 described above. As shown in FIG. 10, in the case of the laser beam L1 with pulse pitches of 10 μm, 5 μm, and 2.5 μm, a ripple pattern is generated on the laser annealing line 100x, mirror finishing cannot be attained, and the flattening process is not appropriately performed. On the other hand, as shown in FIG. 10, in the case of the laser beam L1 with pulse pitches of 1 μm and 0.2 μm, a ripple pattern is not generated on the laser annealing line 100x, mirror finishing can be attained, and the flattening process is appropriately performed. In such a manner, under the condition that the energy and the like are common, the shorter the pulse pitch is, the more appropriately the flattening process is performed. The reason is that the shorter the pulse pitch is, the more continuously the region which is melted through laser annealing and is recrystallized and flattened is formed. The pulse pitch of the laser beam L1 is set to be shorter than at least the pulse pitch of the laser beam L2.

Further, as shown in FIG. 9, the frequency of the laser beam L1 is set to 150 kHz so as to be higher than the frequency of 120 kHz of the laser beam L2, so that the mirror finishing was determined to be acceptable for the laser beam L1. In laser annealing, by applying a next pulse before the irradiation region cools down after irradiation with the laser beam, heat is accumulated and recrystallization is appropriately performed, so that the flattening of the irradiation surface can be realized. In this regard, by increasing the frequency of the laser beam L1 (for example, higher than the frequency of the laser beam L2), the flattening process can be appropriately performed.

In addition, as shown in FIG. 9, by increasing the number of branches of the laser beam L1 in the machining progress direction (here, two branches or four branches), the machining speed can be improved while realizing a short pulse pitch (here, 1 μm). For example, the number of branches of the laser beam L1 in the machining progress direction is set to be larger than the number of branches of the laser beam L2 in the machining progress direction.

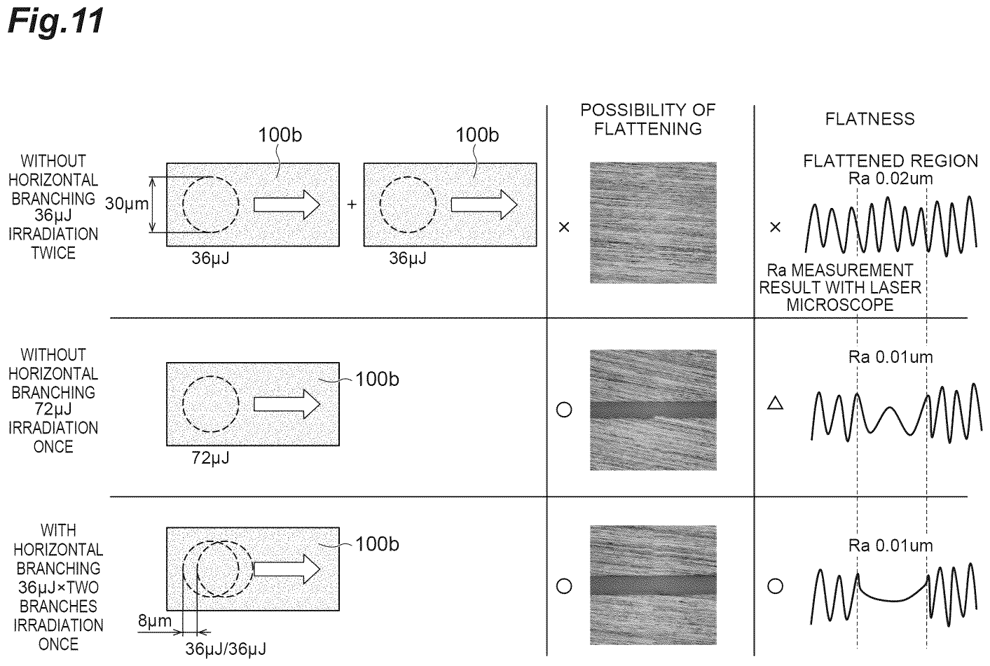

The branching of the laser beam L1 will be described with reference to FIGS. 11 to 13. The branching of the laser beam L1 referred to here does not mean branching in the Z direction (vertical branching), but branching in the X direction and the Y direction (horizontal branching). The horizontal branching of the laser beam L1 includes branching in the machining progress direction and branching in a direction intersecting the machining progress direction (and a direction parallel to the irradiation surface for the laser beam L1). Hereinafter, two examples of the horizontal branching may simply refer to branching in the machining progress direction and branching in the direction intersecting the machining progress direction.

FIG. 11 is a view describing an improvement in flatness by the horizontal branching. In order to improve the flattening effect by laser annealing, the irradiation ranges of horizontally-branched beams of the laser beam L1 may partially overlap each other on the back surface 100b that is an irradiation surface. FIG. 11 shows the results of verifying the flatness of the laser annealing line 100x while changing the conditions of the laser beam L1. In FIG. 11, the upper part shows the possibility of flattening and flatness when the back surface 100b is irradiated twice with the laser beam L1 of 36 μJ without horizontal branching so as not to overlap each other, the middle part shows the possibility of flattening and flatness when the back surface 100b is irradiated once with the laser beam L1 of 72 μJ without horizontal branching, and the lower part shows the possibility of flattening and flatness when the back surface 100b is irradiated once with beams of the laser beam L1 with horizontal branching (36 μJ×2 branches, branch distance 8 μm) so as to overlap each other. The possibility of flattening referred to here indicates whether or not the laser annealing line 100x is formed, and in FIG. 11, “◯” indicates that the laser annealing line 100x is formed, and “X” indicates that the laser annealing line 100x is not formed. In addition, the flatness referred to here indicates the flatness (less unevenness) in a flattened region (laser annealing line 100x), and in FIG. 11, “◯” indicates that the laser annealing line 100x is sufficiently flat, “Δ” indicates that the laser annealing line 100x includes a non-flat region, and “X” indicates that the laser annealing line 100x is not flat to the extent that there is no flattened region. Incidentally, unevenness of the irradiation surface is indicated by waveforms in a region showing flatness in FIG. 11. As described above, the total energy of the laser beam L1 is the same in each example.

As shown at the upper part of FIG. 11, when the back surface 100b is irradiated twice with the laser beam L1 of 36 μJ without horizontal branching so as not to overlap each other, since the energy per point is low, the laser annealing line 100x is not appropriately formed (flattening cannot be attained), the possibility of flattening is “X”, and the flatness is “X”. As shown at the middle part of FIG. 11, when the back surface 100b is irradiated once with the laser beam L1 of 72 μJ without horizontal branching, since the energy per point is higher than in the above-described case, the laser annealing line 100x is formed (the possibility of flattening is “◯”). However, since the laser beam L1 is characterized in that the flatness is convex at the center of the beam and is concave at a location away from the center of the beam, as shown at the middle part of FIG. 11, the flatness is not sufficient for the laser beam L1 of 72 μJ without horizontal branching (flatness is “Δ”). In this regard, as shown at the lower part of FIG. 11, when the back surface 100b is irradiated with beams of the laser beam L1 with horizontal branching (36 μJ×2 branches, branch distance 8 μm) so as to overlap each other, even in a case where the energy per point is low, the laser annealing line 100x is appropriately formed by the two branched beams (the possibility of flattening is “◯”). In addition, since irradiation is performed with the beams so as to overlap each other (such that the irradiation ranges overlap each other), even in a case where there is unevenness in flatness between the center of each beam and the location away from the center of each beam, the unevenness is suppressed by the beams overlapping each other, so that the flatness is also “◯”. In such a manner, by causing the irradiation ranges of the branched beams of the laser beam L1 to partially overlap each other on the back surface 100b, the flatness in the flattening process can be improved.

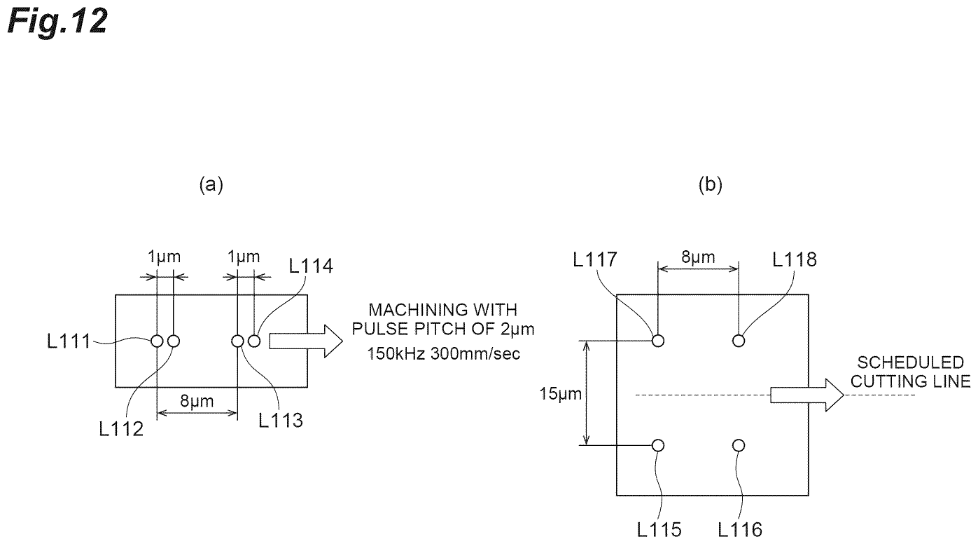

FIG. 12 is a view describing a reduction in tact time and an increase in flattening width by horizontal branching. FIG. 12(a) shows an example of four branches in the machining progress direction. In the example shown in FIG. 12(a), in a state where the above-described two branches for improving the flatness (two branches with a distance of 8 μm) are performed, two branches with a distance of 1 μm are further performed. Namely, as shown in FIG. 12(a), the laser beam L1 is branched into two beams such that a distance between condensing points L111 and L113 is 8 μm, and each beam is further branched into two beams such that a distance between condensing points L111 and L112 and a distance between condensing points L113 and L114 is 1 μm. When irradiation is performed with the laser beam L1 branched into a total of four beams in such a manner, while improving the flatness in the flattening process through the overlapping of the beams with a distance of 8 μm as described above, the pulse pitch can be lengthened by performing irradiation with the beams with a distance of 1 μm, so that the machining speed can be increased. Namely, for example, when the number of branches in the machining progress direction is 1, in order to set the distance between beams to 1 μm, the pulse pitch needs to be set to 1 μm; however, as shown in FIG. 12(a), when irradiation is performed with beams branched by a distance of 1 μm in the machining progress direction, in order to set the distance between the beams to 1 μm, the pulse pitch may be set to 2 μm. In such a manner, the machining speed can be increased by lengthening the pulse pitch. Namely, a reduction in tact time can be realized by branching in the machining progress direction.

FIG. 12(b) shows an example of branches in the direction intersecting the machining progress direction. In more detail, FIG. 12(b) shows an example of a total of four branches: two branches in the machining progress direction and two branches in the direction intersecting the machining progress direction. FIG. 12(b) shows condensing points L115, L116, L117, and L118 of four branched beams of the laser beam L1. In the example shown in FIG. 12(b), the laser beam L1 is branched such that a distance between the condensing point L115 and the condensing point L116 facing each other in the machining progress direction and a distance between the condensing point L117 and the condensing point L118 facing each other in the machining progress direction is 8 μm, and such that a distance between the condensing point L115 and the condensing point L117 facing each other in the direction intersecting the machining progress direction and a distance between the condensing point L116 and the condensing point L118 facing each other in the direction intersecting the machining progress direction is 15 μm. In such a manner, by branching the laser beam L1 in the direction intersecting the machining progress direction, the width of the laser annealing line 100x (length in the direction intersecting the machining progress direction) flattened by laser annealing using the laser beam L1 can be increased. For this reason, the number of branches of the laser beam L1 for laser annealing in the direction intersecting the machining progress direction may be larger than the number of branches of the laser beam L2 for forming a modified layer in the direction intersecting the machining progress direction. Then, similarly, from the viewpoint of widening the laser annealing region (annealing width), the laser beam L1 may have a top-hat shape rather than a Gaussian shape. In addition, the annealing width may be adjusted by adjusting the positions of the condensing points. Namely, when the annealing width is desired to be widened, the positions of the condensing points may be set to be deep, and when the annealing width is desired to be narrowed, the positions of the condensing points may be set to be shallow.

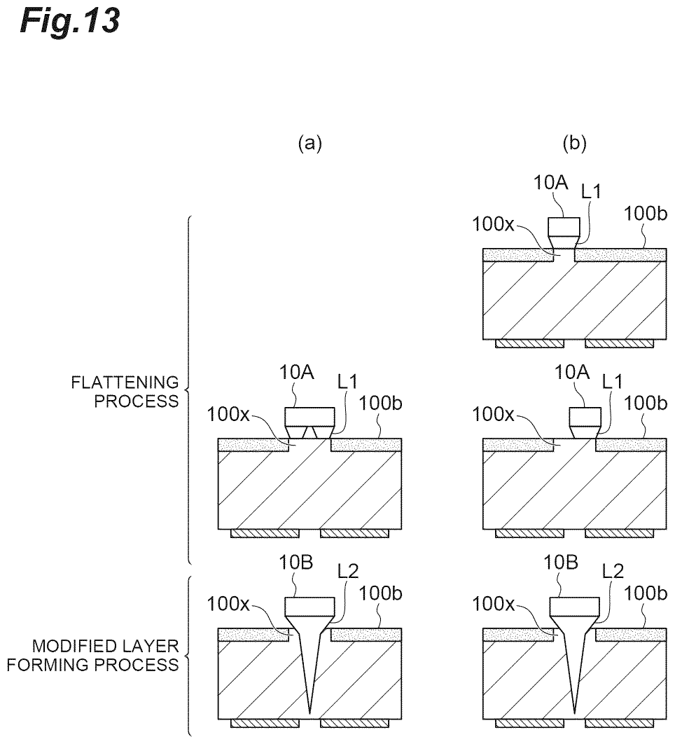

FIG. 13 is a view describing the effect of branching the laser beam L1 in the direction intersecting the machining progress direction. FIG. 13(a) shows an example in which the modified layer forming process is performed using the laser beam L2 after the laser beam L1 is branched in the direction intersecting the machining progress direction to form the laser annealing line 100x with a predetermined width (after the flattening process is performed). FIG. 13(b) shows an example in which the modified layer forming process is performed using the laser beam L2 after irradiation is performed twice with the laser beam L1 in the direction intersecting the machining progress direction to form the laser annealing line 100x with the predetermined width (after the flattening process is performed). The laser annealing line 100x with the predetermined width can be formed by the laser beam L1 in both machining operations; however, in the example shown in FIG. 13(b), irradiation is performed twice with the laser beam L1 (two passes are required), whereas in the example shown in FIG. 13(a), the laser annealing line 100x with the predetermined width can be formed by performing irradiation once with the laser beam L1 through branching the laser beam L1 in the direction intersecting the machining progress direction. In such a manner, when the width of the laser annealing line 100x is large to some extent, by branching the laser beam L1 in the direction intersecting the machining progress direction, the number of passes of irradiation with the laser beam L1 can be reduced, and the time required for the flattening process can be shortened.

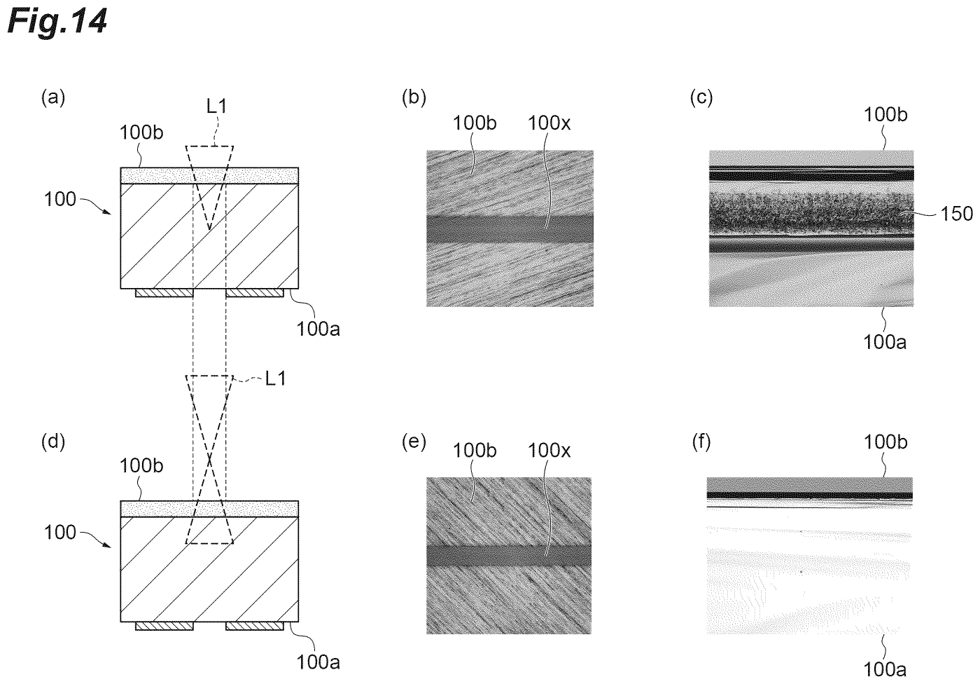

Here, for example, when the laser beam L1 is a transmissive laser, a modified layer may also be formed inside the object 100 by the laser beam L1 for the flattening process. FIG. 14 is a view showing one example of laser annealing and the formation of a modified layer for each condensing position. FIG. 14(a) shows a case where laser annealing is performed such that the condensing point of the laser beam L1 is located inside the object 100. In this case, in addition to forming the laser annealing line 100x on the back surface 100b using the laser beam L1 as shown in FIG. 14(b), the modified layer 150 can be formed inside the object 100 as shown in FIG. 14(c). Since the laser beam L1 for laser annealing has a shorter pulse pitch than the laser beam L2 for forming a modified layer, even when the modified layer 150 is formed, it is difficult for a crack to extend from the modified layer 150. For this reason, normally, the modified layer itself formed by the laser beam L1 does not become the starting point of division, but thereafter, when a modified layer with a long pulse pitch is formed by the laser beam L2, a crack occurring from the modified layer formed by the laser beam L2 leads to the above-described crack of the modified layer formed by the laser beam L1, and the crack of the modified layer formed by the laser beam L1 assists the division. In this case, the number of passes of the laser beam L2 for forming a modified layer can be reduced. When such an effect is expected, in the first step (step of flattening the irradiation surface through laser annealing), the irradiation surface is irradiated with the laser beam L1 such that the irradiation surface is flattened and the modified layer is formed inside the object 100.

On the other hand, when the laser beam L1 for laser annealing is desired to be used only for the flattening process, in the first step, the irradiation surface may be irradiated with the laser beam L1 such that the modified layer is not formed inside the object 100. Specifically, in the first step, as shown in FIG. 14(d), the condensing point of the laser beam L1 may be set to a position outside the object 100 (for example, a position above the object 100). In this case, while forming the laser annealing line 100x on the back surface 100b using the laser beam L1 as shown in FIG. 14(e), the formation of the modified layer inside the object 100 by the laser beam L1 can be prevented as shown in FIG. 14(f). In this case, regarding the formation of the laser annealing line 100x, by setting approximately the same irradiation area as in the case of condensing the laser beam inside the object 100, the flattening process can be performed in the same manner as in the case of condensing the laser beam inside the object 100. Incidentally, even when the condensing point of the laser beam L1 is set to a position outside the object 100, the modified layer may be formed in the vicinity of the irradiation surface depending on other conditions.

Next, one example of machining conditions will be described. An example where the flattening process and the modified layer forming process are performed on a silicon wafer with a wafer thickness of 300 μm (crystal orientation <100>). When the laser beam L1 and the laser beam L2 are the same type of laser emitted from a common light source, for example, it can be considered that the wavelength of the laser beam L1 for laser annealing is set to 1099 nm, the pulse width is set to 700 nsec, the frequency is set to 150 kHz, the machining speed is set to 150 mm/sec, the pulse pitch is set to 1 μm, there is horizontal branching in the machining progress direction (branch distance 8 μm), the condensing point is set outside (above) the object 100, and the total output is set to 14 W. In addition, for example, it can be considered that the wavelength of the laser beam L2 for forming a modified layer is set to 1099 nm, the pulse width is set to 700 nsec, the frequency is set to 120 kHz, the machining speed is set to 800 mm/sec, the pulse pitch is set to 6.67 μm, and the outputs for forming modified layers at different depths are set to 2.78 W and 1.85 W. When the laser beam L1 and the laser beam L2 are emitted from separate light sources, for example, it can be considered that the wavelength of the laser beam L1 for laser annealing is set to 1064 nm, the pulse width is set to 9 psec, the frequency is set to 1 MHz, the machining speed is set to 1000 mm/sec, the pulse pitch is set to 1 μm, the total output is set to 30 W, and the burst number of burst pulses is set to 2. The burst referred to here is a division of each pulse, and the same effect as the above-described branching of the laser beam is obtained. In addition, for example, it can be considered that the wavelength of the laser beam L2 for forming a modified layer is set to 1099 nm, the pulse width is set to 700 nsec, the frequency is set to 120 kHz, the machining speed is set to 800 mm/sec, the pulse pitch is set to 6.67 μm, and the outputs for forming modified layers at different depths are set to 2.78 W and 1.85 W.

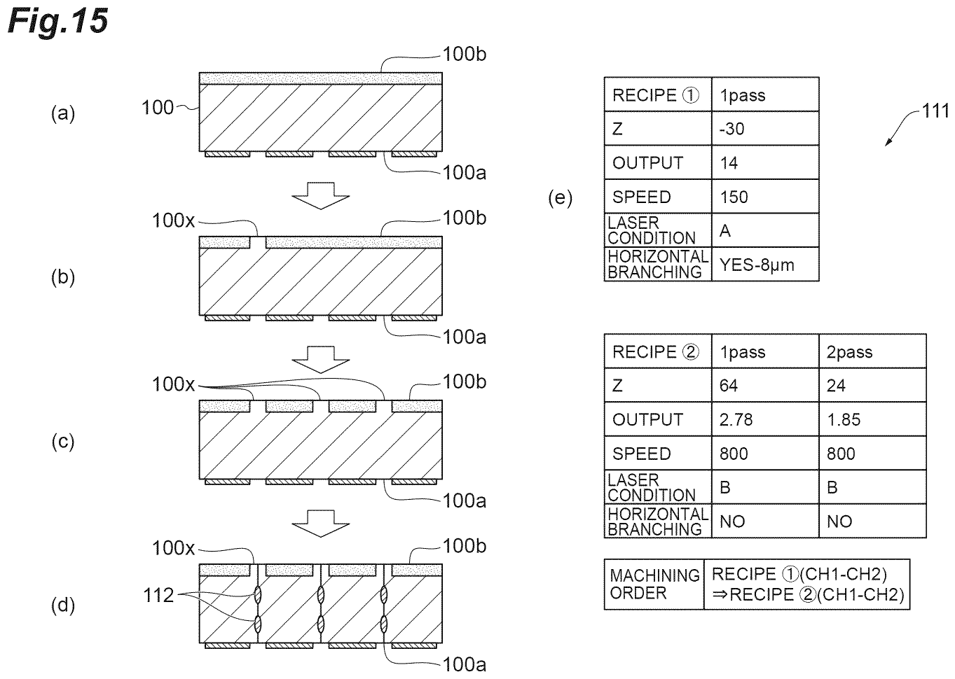

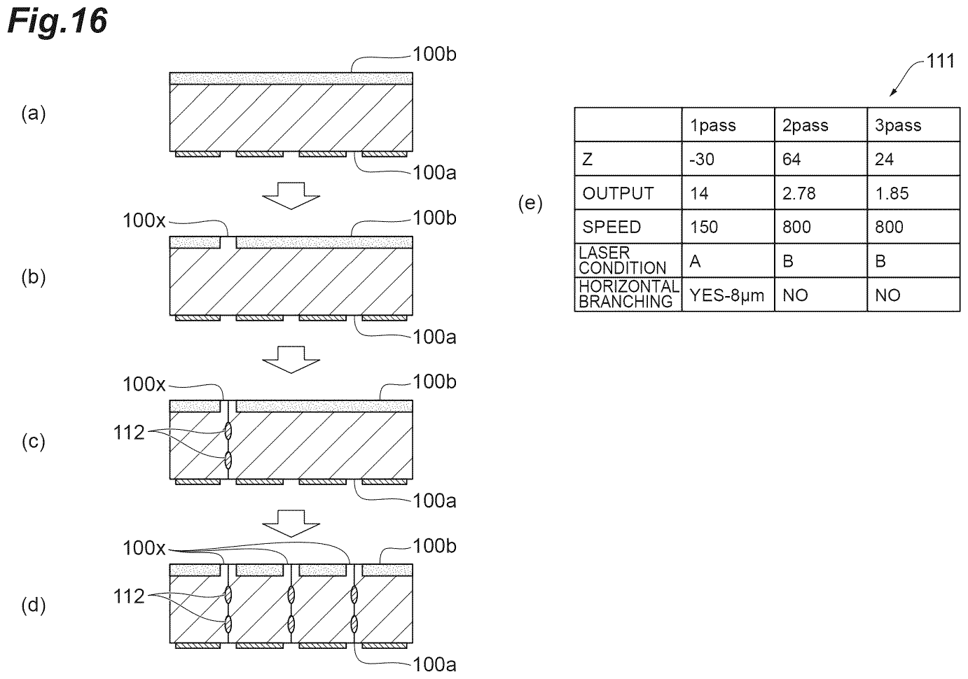

Next, referring to FIGS. 15 and 16, a setting screen of a GUI 111 for performing the first step related to the flattening process and the second step related to the modified layer forming process described above will be described. FIGS. 15(a) to 15(d) and FIGS. 16(a) to 16(d) schematically show the steps to be performed, and FIGS. 15(e) and 16(e) show the setting screen of the GUI 111. As shown in FIGS. 15(a) to 15(d), the object 100 is prepared (refer to FIG. 15(a)), the flattening process is performed such that the laser annealing lines 100x are formed on all dicing lines (refer to FIGS. 15(b) and 15(c)), and after all the laser annealing lines 100x are formed, stealth dicing machining is performed along each of the laser annealing lines 100x to form a modified layer 112 (refer to FIG. 15(d)). In this case, in the setting screen of the GUI 111, as shown in FIG. 15(e), Recipe 1 related to the flattening process and Recipe 2 related to the modified layer forming process are set. In Recipe 1, the Z height, the output, the machining speed, the laser condition, and the presence or absence of horizontal branching for one pass are set. The Z height is a term indicating a machining depth when laser machining is performed. For example, when a modified layer is not desired to be formed by the laser beam L1 for laser annealing, the condensing point of the laser beam L1 is set to a position above the object 100. In this case, the Z height has, for example, a negative value. In Recipe 1, the Z height is set to “−30”, the output is set to “14 μJ”, the machining speed is set to “150 mm/sec”, the laser condition is set to “A”, and horizontal branching is set to “yes—8 μm”. The laser condition “A” refers to conditions of the laser beam L1 which are selectably set in advance, and refers to, for example, conditions such as a pulse width of 700 nsec and a frequency of 150 kHz. The horizontal branching “yes—8 μm” indicates that there is horizontal branching and the branch distance is 8 μm. In addition, in Recipe 2 related to the modified layer forming process, the Z height, the output, the speed, the laser condition, and the presence or absence of horizontal branching for two passes related to forming two modified layers 112 at different depths are set. In Recipe 2, regarding the first pass, the Z height is set to “64”, the output is set to “2.78 μJ”, the machining speed is set to “800 mm/sec”, the laser condition is set to “B”, and horizontal branching is set to “no”. In addition, regarding the second pass, the Z height is set to “24”, the output is set to “1.85 μJ”, the machining speed is set to “800 mm/sec”, the laser condition is set to “B”, and horizontal branching is set to “no”. The laser condition “B” refers to conditions of the laser beam L2 which are selectably set in advance, and refers to, for example, conditions such as a pulse width of 700 nsec and a frequency of 120 kHz. Incidentally, the pulse pitch can be calculated as the machining speed divided by the frequency, but in the example shown in FIG. 15(e), is not displayed on the setting screen of the GUI 111. The setting screen of the GUI 111 displays the machining order of the two recipes (Recipe 1 first, Recipe 2 later).

As shown in FIGS. 16(a) to 16(d), the object 100 is prepared (refer to FIG. 16(a)), the flattening process is performed such that one laser annealing line 100x is formed on one dicing line (refer to FIG. 16(b)), stealth dicing machining is performed along the formed one laser annealing line 100x to form the modified layer 112 (refer to FIG. 16(c)), and the processes shown in FIGS. 16(b) and 16(c) are performed on all dicing lines to form the modified layers 112 for all the dicing lines (refer to FIG. 16(d)). Namely, it is assumed that the scanning of the flattening process and the scanning of the modified layer forming process are repeatedly performed for each dicing line. In this case, on the setting screen of the GUI 111, as shown in FIG. 16(e), the first pass is for the flattening process, the second pass and the third pass are for the modified layer forming process, and the Z height, the output, the machining speed, the laser condition, and the presence or absence of horizontal branching are set for each pass. In the recipe shown in FIG. 16(e), regarding the first pass, the Z height is set to “−30”, the output is set to “14 μJ”, the machining speed is set to “150 mm/sec”, the laser condition is set to “Δ”, and horizontal branching is set to “yes—8 μm”. In addition, regarding the second pass, the Z height is set to “64”, the output is set to “2.78 μJ”, the machining speed is set to “800 mm/sec”, the laser condition is set to “B”, and horizontal branching is set to “no”. In addition, regarding the third pass, the Z height is set to “24”, the output is set to “1.85 μJ”, the machining speed is set to “800 mm/sec”, the laser condition is set to “B”, and horizontal branching is set to “no”.

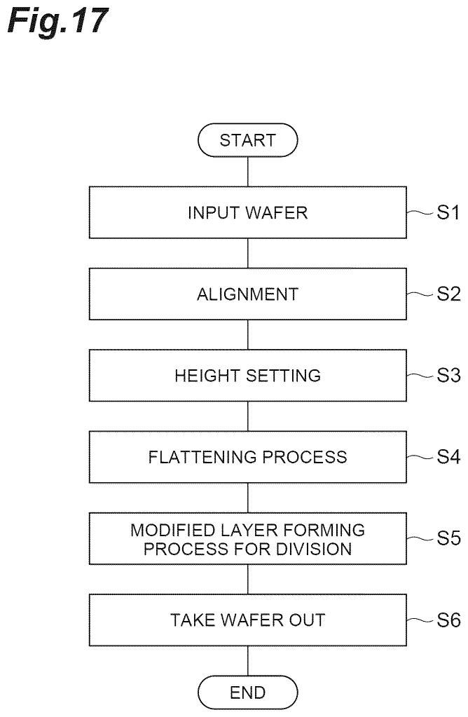

Next, referring to FIG. 17, a laser machining method including the flattening process and the modified layer forming process, which is performed by the laser machining device 1 according to the present embodiment will be described. FIG. 17 is a flowchart showing the laser machining method including the flattening process and the modified layer forming process.

As shown in FIG. 17, in the laser machining method, first, the object 100 that is a wafer is input to the laser machining device 1, and the object 100 is supported by the support unit 7 (step S1). Then, the alignment of the irradiation positions of a laser beam is performed (step S2). Subsequently, the Z height is set based on a set recipe (step S3).

Subsequently, the flattening process is performed (step S4). Specifically, the control unit 9 controls the light source 81 and the movement mechanism 6 such that the back surface 100b of the object 100 is irradiated with the laser beam L1 to flatten the back surface 100b, which is an irradiation surface, through laser annealing.

Subsequently, the modified layer forming process for forming a modified layer for dividing the object 100 is performed (step S5). Specifically, the control unit 9 controls the light source 82 and the movement mechanism 6 such that the back surface 100b (irradiation surface) which is flattened is irradiated with the laser beam L2 to form a modified layer inside the object 100. Finally, the object 100 that is a wafer is taken out from the laser machining device 1 (step S6).

### Another Example of Machining by Laser Machining Device (IR Grooving+Stealth Dicing)

Next, another example of machining of the object 100 by the laser machining device 1 will be described. Here, an example in which the laser machining device 1 performs stealth dicing machining on the object 100 after IR grooving will be described.

The IR grooving referred to here is a process in which the functional elements formed on the surface 100a of the object 100 are irradiated with a laser beam from a back surface 100b side to form a weakened region in the functional elements. The weakened region is a region in which the functional elements are weakened. Weakening includes embrittling. The weakened region can also be said to be a region in which traces have occurred due to the laser irradiation, and is a region that is more likely to be cut or break compared to a non-processed region. Incidentally, the weakened region may be formed continuously in a line shape in at least partial regions of the functional elements, or may be intermittently formed according to the pulse pitch of the laser irradiation.

Here, when there is a damage to the back surface 100b to be irradiated with the laser beam in the IR grooving, the IR grooving with the laser beam incident from the back surface 100b is not appropriately performed on the functional elements on the surface 100a (device surface), which is a risk, and the usable energy is limited, which is a problem. Therefore, in this mode, before the IR grooving is performed, the flattening process is performed on the back surface 100b of the object 100 through laser annealing.

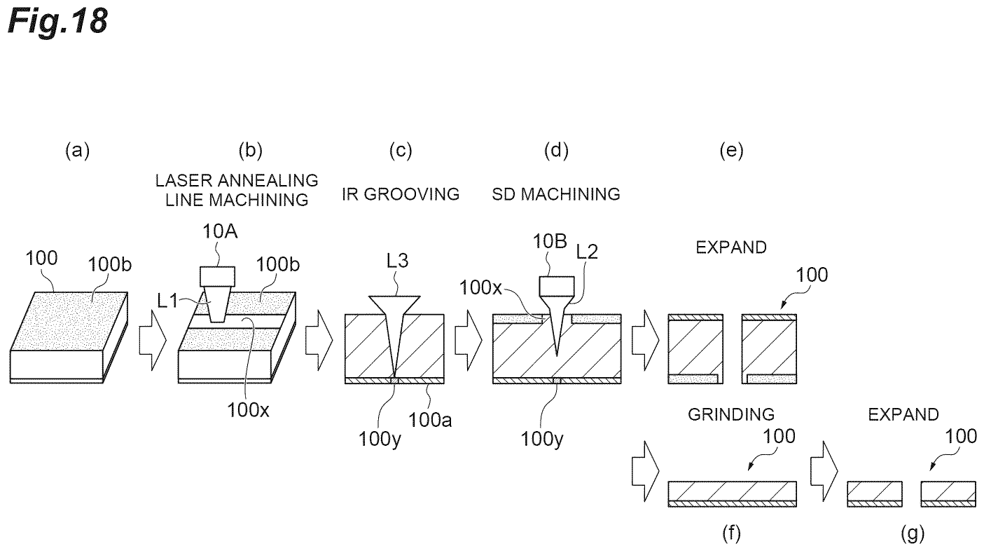

FIG. 18 is a view describing the flattening process and the IR grooving and the modified layer forming process after the flattening process. As shown in FIG. 18(a), first, the object 100 is prepared, and the object 100 is supported by the support unit 7 (refer to FIG. 1). Subsequently, as shown in FIG. 18(b), the movement mechanism 6 controlled by the control unit 9 moves the laser machining head 10A such that the condensing points of the laser beam L1 are located along one line extending in one direction on the back surface 100b, and the light source 81 controlled by the control unit 9 outputs the laser beam L1 for laser annealing. The light source 81 referred to here is, for example, a light source that emits an ultrashort pulse laser. Namely, the control unit 9 performs the first control to control the light source 81 and the movement mechanism 6 such that the back surface 100b of the object 100 is irradiated with the laser beam L1 to flatten the back surface 100b, which is an irradiation surface, through laser annealing. The first control is control related to the first step (flattening process) of flattening the back surface 100b through laser annealing by irradiating the back surface 100b with the laser beam L1. In the first step, the back surface 100b before an IR grooving (first grooving) step is irradiated with the laser beam L1 using the back surface 100b as an irradiation surface. Accordingly, the above-described one line becomes the laser annealing line 100x on which laser annealing is performed. The laser annealing line 100x includes at least a line (namely, a dicing line) to be irradiated with the laser beam in the IR grooving.

Subsequently, as shown in FIG. 18(c), the movement mechanism 6 controlled by the control unit 9 moves the laser machining head 10A such that the condensing points of a laser beam L3 for the IR grooving are located along the laser annealing line 100x described above, and the light source 81 (for example, a light source that emits an ultrashort pulse laser) controlled by the control unit 9 outputs the laser beam L3 for the IR grooving. Namely, the control unit 9 performs a first grooving control to control the light source 81 and the movement mechanism 6 such that irradiation is performed with the laser beam L3 from the back surface 100b of the object 100 to form a weakened region 100y in the functional element layer on the surface 100a. The first grooving control is control related to the first grooving step (IR grooving) of forming the weakened region 100y on the surface 100a by performing irradiation with the laser beam L3 from the back surface 100b of the object 100 before the second step related to the modified layer forming process. Accordingly, the IR grooving is performed on the functional elements on the surface 100a, and the weakened region 100y is formed in the functional elements.

Then, as shown in FIG. 18(d), the movement mechanism 6 controlled by the control unit 9 moves the laser machining head 10B such that the condensing points of the laser beam L2 are located along the laser annealing line 100x described above, and the light source 82 controlled by the control unit 9 outputs the laser beam L2 for forming a modified layer. The light source 82 referred to here is, for example, a light source that emits a nanosecond pulse laser. Namely, the control unit 9 performs the second control to control the light source 82 and the movement mechanism 6 such that the back surface 100b (irradiation surface) which is flattened is irradiated with the laser beam L2 to form a modified layer inside the object 100. The second control is control related to the second step (modified layer forming process) of forming a modified layer inside the object 100 by irradiating the back surface 100b, which is flattened in the first step, with the laser beam L2. After the modified layer is formed in such a manner, the expanding process (FIG. 18(e)) is performed in the dividing step to cut the object 100 into a plurality of chips. Incidentally, after the modified layer is formed, the grinding process (refer to FIG. 18(f)) may be performed, and then the expanding process (FIG. 18(g)) may be performed.

Incidentally, one example of machining conditions of the IR grooving is as follows. For example, when the IR grooving is performed on a patterned film of a silicon wafer with a wafer thickness of 300 μm (crystal orientation <100>), it can be considered that in one pass, the burst number of burst pulses is set to 15, the output is set to 5.6 μJ×15=total 84 μJ, the machining speed is set to 500 mm/sec, and the pulse pitch is set to 5 μm. In addition, for example, when the IR grooving is performed on a patterned metal pad and a patterned film, it can be considered that two passes are performed, and regarding the first pass, the burst number is set to 2, the output is set to 8.5 μJ×2=total 17 μJ, the machining speed is set to 300 mm/sec, and the pulse pitch is set to 3 μm, and regarding the second pass, the burst number is set to 15, the output is set to 5.6 μJ×15=total 84 μJ, the machining speed is set to 500 mm/sec, and the pulse pitch is set to 5 μm.

In the above-described example, the light source 81 for the flattening process and the light source 81 for the IR grooving have been described as being common (for example, a light source that emits a transmissive ultrashort pulse laser); however, the present invention is not limited thereto, and the light source for the flattening process and the light source for the IR grooving may be separated. In that case, for example, the light source for the flattening process may be a light source that emits light with an absorptive wavelength such as 532 nsec. In addition, the light source for the IR grooving may be a light source (for example, a light source that emits a nanosecond pulse laser) common to the light source for the modified layer forming process. In addition, for example, when the light source for the flattening process and the light source for the IR grooving are common, the laser dicer for the flattening process and the IR grooving and the laser dicer for the modified layer forming process may be common or may be provided as separate devices.

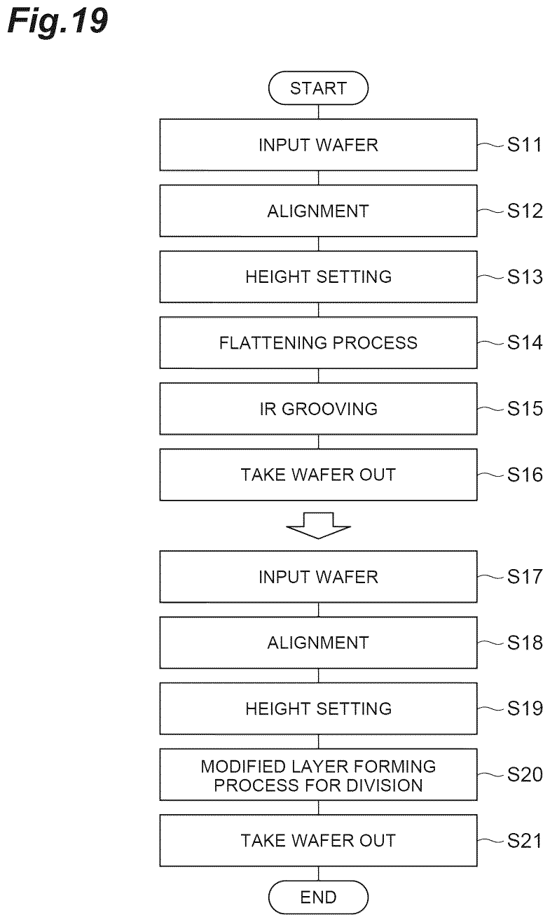

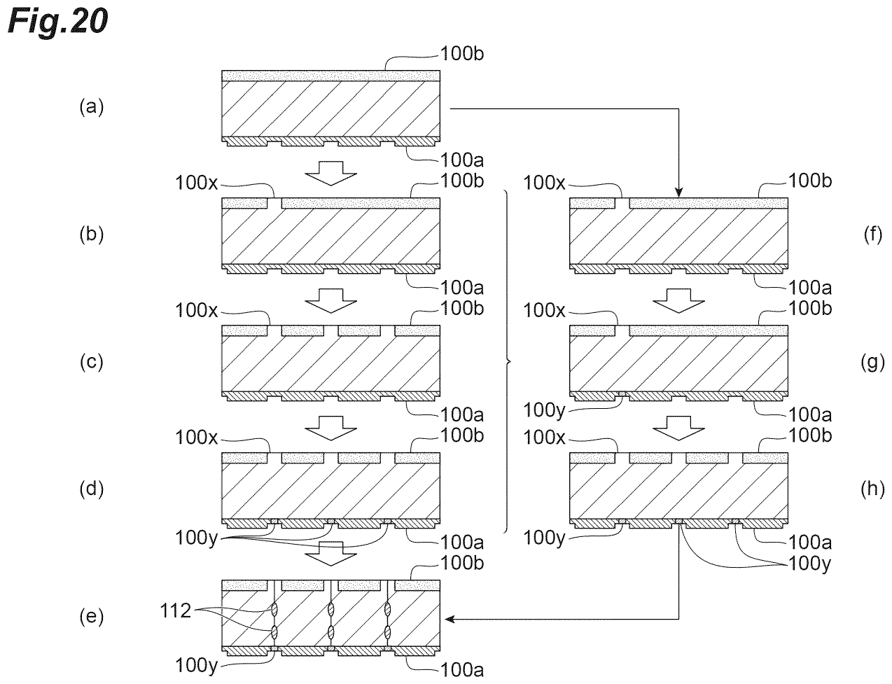

Next, referring to FIGS. 19 and 20, a laser machining method including the flattening process, the IR grooving, and the formation of a modified layer, which is performed by the laser machining device 1 according to the present embodiment will be described. FIG. 19 is a flowchart showing the laser machining method including the flattening process, the IR grooving, and the formation of a modified layer. FIG. 20 is a view schematically showing one example of the flattening process and the IR grooving and the modified layer forming process after the flattening process. Hereinafter, one example of processing when the device for the flattening process and the IR grooving and the device for the modified layer forming process are separate devices will be described. Incidentally, the light source for the flattening process and the IR grooving is a common light source that emits an ultrashort pulse laser, and will be described as the “light source 81” described above. In addition, here, the light source for the modified layer forming process is a light source of the device different from the device for the flattening process and the IR grooving, but for convenience of description, is referred to as the “light source 82”.

As shown in FIG. 19, in the laser machining method, first, the object 100 that is a wafer is input to the device for the flattening process and the IR grooving in the laser machining device 1 (step S11). The object 100 is set such that the back surface 100b can be irradiated with a laser beam (refer to FIG. 20(a)). Then, the alignment of the irradiation positions of the laser beam is performed (step S12). Subsequently, the Z height is set based on a set recipe (step S13).

Subsequently, the flattening process is performed (step S14). Specifically, the control unit 9 controls the light source 81 and the movement mechanism 6 such that the back surface 100b of the object 100 is irradiated with the laser beam L1 to flatten the back surface 100b, which is an irradiation surface, through laser annealing. Regarding the flattening process, all the laser annealing lines 100x are sequentially formed line by line (refer to FIGS. 20(b) and 20(c)).

Subsequently, after all the laser annealing lines 100x are formed, the IR grooving is performed (step S15). Specifically, the control unit 9 controls the light source 81 and the movement mechanism 6 such that irradiation is performed with the laser beam L3 from each of the laser annealing lines 100x on the back surface 100b of the object 100 to form the weakened region 100y in the functional element layer on the surface 100a (refer to FIG. 20(d)). Then, the object 100 that is a wafer is taken out from the device for the flattening process and the IR grooving in the laser machining device 1 (step S16).

Incidentally, in the description of the flattening process and the IR grooving, after all the laser annealing lines 100x are formed, each of the weakened regions 100y is formed by performing irradiation with the laser beam L3 from each of the laser annealing lines 100x on the back surface 100b; however, the present invention is not limited thereto. Namely, in the flattening process and the IR grooving, after the laser annealing lines 100x are formed (refer to FIG. 20(f)), all the weakened regions 100y may be formed (refer to FIG. 20(h)) by repeatedly performing the process for each line, in which irradiation is performed with the laser beam L3 from the laser annealing line 100x to form the weakened region 100y in the functional element layer on the surface 100a (FIG. 20(g)).

In step S16, the object 100 that is a wafer for which the processing up to step S16 is completed is input to the device for the modified layer forming process in the laser machining device 1 (step S17). Then, the alignment of the irradiation positions of the laser beam is performed (step S18). Subsequently, the Z height is set based on the set recipe (step S19).

Subsequently, the modified layer forming process for forming a modified layer for dividing the object 100 is performed (step S20). Specifically, the control unit 9 controls the light source 82 and the movement mechanism 6 such that the back surface 100b (irradiation surface) which is flattened is irradiated with the laser beam L2 to form the modified layer 112 inside the object 100 (refer to FIG. 20(e)). Finally, the object 100 that is a wafer is taken out from the laser machining device 1 (step S21).

### Another Example of Machining by Laser Machining Device (Surface Laser Grooving+Stealth Dicing)

Next, another example of machining of the object 100 by the laser machining device 1 will be described. Here, an example in which the laser machining device 1 performs stealth dicing machining on the object 100 after surface laser grooving will be described.

The surface laser grooving referred to here is a process for removing surface layers of dicing streets on the surface 100a before the modified layer forming process. The surface layer is a TEG or film on each of the dicing streets. The occurrence of film peeling or the like when each functional element of the object 100 is made into a chip can be suppressed by performing such surface laser grooving.

Here, after the surface laser grooving, a bottom surface of a groove formed on the surface 100a by the surface laser grooving may be roughened. In this case, stealth dicing machining cannot be performed from the surface 100a after the surface laser grooving, and it is necessary to once make a transfer to the back surface 100b and perform irradiation with the laser beam for forming a modified layer from the back surface 100b. In this case, the transfer cost increases, which is a problem. Therefore, in this mode, after the surface laser grooving and before the modified layer forming process, the flattening process is performed on the surface 100a of the object 100 through laser annealing.

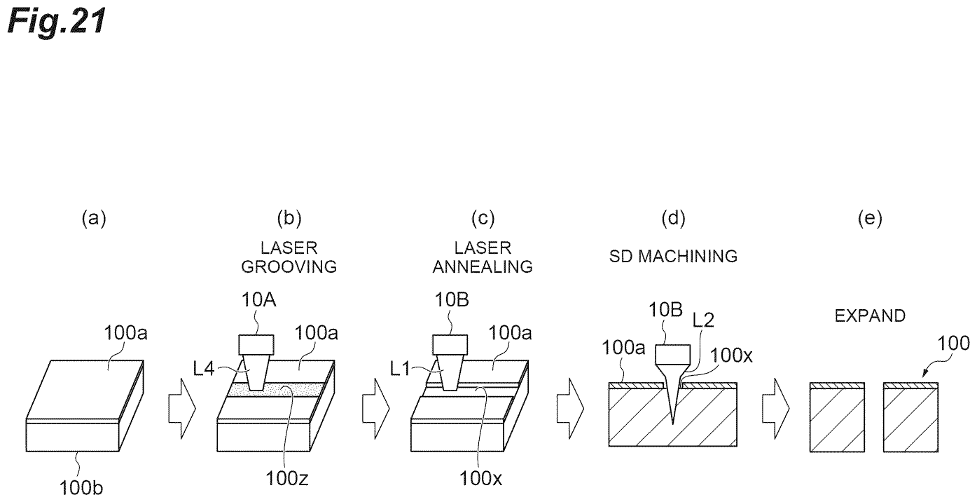

FIG. 21 is a view describing laser grooving and the flattening process and the modified layer forming process after the laser grooving. As shown in FIG. 21(a), first, the object 100 is prepared, and the object 100 is supported by the support unit 7 (refer to FIG. 1). Subsequently, as shown in FIG. 21(b), the movement mechanism 6 controlled by the control unit 9 moves the laser machining head 10A such that the condensing points of a laser beam L4 for the surface laser grooving are located along one line extending in one direction on the surface 100a, and the light source 81 (for example, a light source that emits an ultrashort pulse laser) controlled by the control unit 9 outputs the laser beam L4 for the surface laser grooving. Namely, the control unit 9 performs a second grooving control to control the light source 81 and the movement mechanism 6 such that the surface 100a of the object 100 is irradiated with the laser beam L4 to remove a surface layer of the surface 100a. The second grooving control is control related to a second grooving step (surface laser grooving) of removing the surface layer of the surface 100a by irradiating the surface of the object 100 with the laser beam L4. A bottom surface 100z of a groove on which the surface laser grooving is performed becomes a rough surface.

Subsequently, as shown in FIG. 21(c), the movement mechanism 6 controlled by the control unit 9 moves the laser machining head 10B such that the condensing points of the laser beam L1 are located along the bottom surface 100z of the groove described above, and the light source 82 controlled by the control unit 9 outputs the laser beam L1 for laser annealing. The light source 82 referred to here is, for example, a light source that emits a nanosecond pulse laser. Namely, the control unit 9 performs the first control to control the light source 82 and the movement mechanism 6 such that the bottom surface 100z of the groove of the surface 100a of the object 100 is irradiated with the laser beam L1 to cause the bottom surface 100z to become the laser annealing line 100x, which is flattened, through laser annealing. The first control is control related to the first step (flattening process) of flattening the surface 100a through laser annealing by irradiating the surface 100a with the laser beam L1. In the first step, the bottom surface 100z of the groove formed on the surface 100a by the surface laser grooving (second grooving) step is irradiated with the laser beam L1 using the bottom surface 100z as an irradiation surface, to flatten the bottom surface 100z of the groove (becoming the laser annealing line 100x).

Subsequently, as shown in FIG. 21(d), the movement mechanism 6 controlled by the control unit 9 moves the laser machining head 10B such that the condensing points of the laser beam L2 are located along the laser annealing line 100x, and the light source 82 controlled by the control unit 9 outputs the laser beam L2 for forming a modified layer. The light source 82 referred to here is, for example, a light source that emits a nanosecond pulse laser. The control unit 9 performs the second control to control the light source 82 and the movement mechanism 6 such that the bottom surface 100z (namely, the laser annealing line 100x) which is flattened is irradiated with the laser beam L2 to form a modified layer inside the object 100. The second control is control related to the second step (modified layer forming process) of forming a modified layer inside the object 100 by irradiating the bottom surface 100z (namely, the laser annealing line 100x), which is flattened in the first step, with the beam L2. After the modified layer is formed in such a manner, the expanding process (FIG. 21(e)) is performed in the dividing step to cut the object 100 into a plurality of chips.

In the above-described example, the light source 81 for the surface laser grooving and the light source 82 for the flattening process have been described as being separately provided; however, the present invention is not limited thereto, and the light source for the surface laser grooving and the light source for the flattening process may be common (for example, a light source that emits an ultrashort pulse laser). In addition, for example, when the light source for the surface laser grooving and the light source for the flattening process are separately provided, the laser dicer for the surface laser grooving and the laser dicer for the flattening process and the modified layer forming process may be common or may be provided as separate devices.

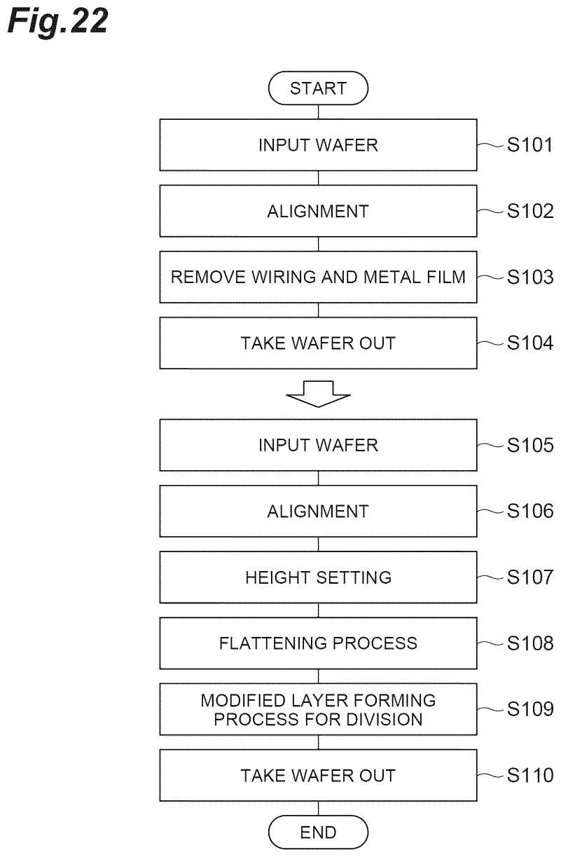

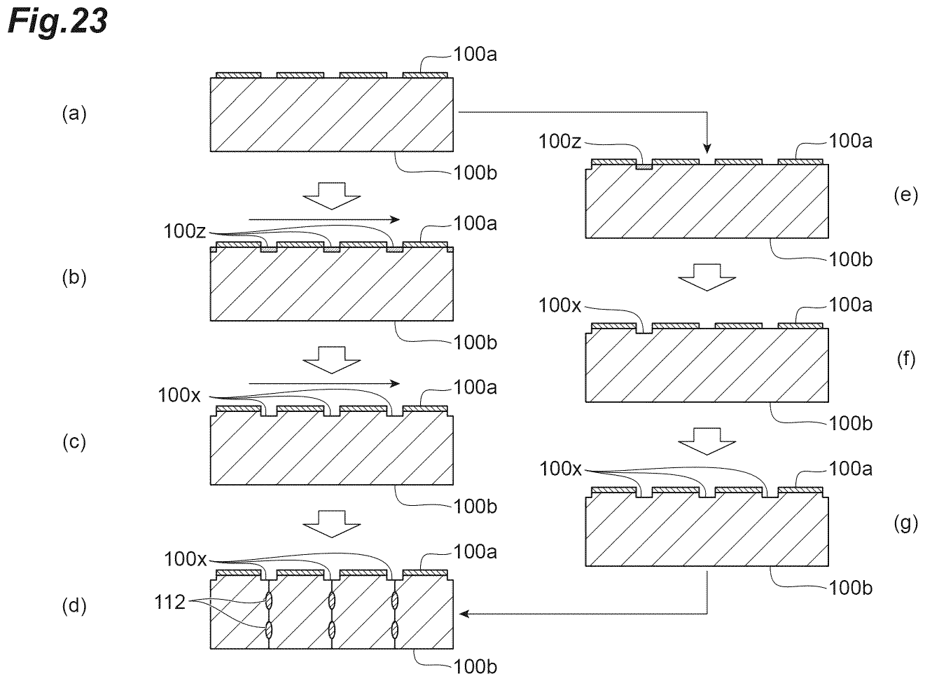

Next, referring to FIGS. 22 and 23, a laser machining method including the laser grooving, the flattening process, and the modified layer forming process, which is performed by the laser machining device 1 according to the present embodiment will be described. FIG. 22 is a flowchart showing the laser machining method including the laser grooving, the flattening process, and the modified layer forming process. FIG. 23 is a view schematically showing one example of the laser grooving and the flattening process and the modified layer forming process after the laser grooving. Hereinafter, one example of processing when the device for the surface laser grooving and the device for the flattening process and the modified layer forming process are separate devices will be described. Incidentally, the light source for the surface laser grooving is a common light source that emits an ultrashort pulse laser, and will be described as the “light source 81” described above. In addition, here, the light source for the flattening process and the modified layer forming process is a light source of the device different from the device for the surface laser grooving, but for convenience of description, is referred to as the “light source 82”.

As shown in FIG. 22, in the laser machining method, first, the object 100 that is a wafer is input to the device for the surface laser grooving in the laser machining device 1 (step S101). The object 100 is set such that the back surface 100b can be irradiated with a laser beam (refer to FIG. 23(a)). Then, the alignment of the irradiation positions of the laser beam is performed (step S102). Subsequently, the surface laser grooving is performed to remove a surface layer such as wirings and a metal film of the surface 100a (step S103). Specifically, the control unit 9 controls the light source 81 and the movement mechanism 6 such that the surface 100a of the object 100 is irradiated with the laser beam L4 to remove the surface layer of the surface 100a. The surface laser grooving is performed on all lines line by line (refer to FIG. 23(b)). Accordingly, the bottom surfaces 100z of grooves formed by performing the surface laser grooving on all the lines become rough surfaces. Then, the object 100 that is a wafer is taken out from the device for the surface laser grooving in the laser machining device 1 (step S104).

Subsequently, the object 100 that is a wafer for which the processing up to step S104 is completed is input to the device for the flattening process and the modified layer forming process in the laser machining device 1 (step S105). Then, the alignment of the irradiation positions of the laser beam is performed (step S106). Subsequently, the Z height is set based on a set recipe (step S107).

Subsequently, the flattening process is performed (step S108). Specifically, the control unit 9 controls the light source 82 and the movement mechanism 6 such that the bottom surfaces 100z of the grooves of the surface 100a of the object 100 are irradiated with the laser beam L1 to cause the bottom surfaces 100z to become the laser annealing lines 100x, which are flattened, through laser annealing. Regarding the flattening process, all the laser annealing lines 100x are sequentially formed line by line (refer to FIG. 23(c)).

Subsequently, the modified layer forming process for forming a modified layer for dividing the object 100 is performed (step S109). Specifically, the control unit 9 controls the light source 82 and the movement mechanism 6 such that the bottom surfaces 100z (namely, the laser annealing lines 100x) which are flattened are irradiated with the laser beam L2 to form the modified layers 112 inside the object 100 (refer to FIG. 23(d)). Finally, the object 100 that is a wafer is taken out from the laser machining device 1 (step S110).

Incidentally, regarding the surface laser grooving and the flattening process, a case where after the surface laser grooving is performed on all the lines, the flattening process is performed on each line has been described; however, the present invention is not limited thereto. Namely, in the surface laser grooving and the flattening process, the process in which the surface laser grooving is performed on each line to remove the surface layer, the bottom surface 100z becomes a rough surface (after FIG. 23(e), and then the bottom surface 100z is flattened to become the laser annealing line 100x (refer to FIG. 23(f)) may be repeatedly performed, and the flattening process after the surface laser grooving may be performed on all the lines (refer to FIG. 23(g)). In this case, it can be considered that the surface laser grooving and the flattening process are performed by the same device and the modified layer forming process is performed on the object, of which the flattening is completed, by another device. Alternatively, all the processes may be performed by the same device.

Next, actions and effects of the laser machining method according to the present embodiment will be described.

A laser machining method performed by a laser machining device 1 according to the present embodiment includes: a first step of flattening an irradiation surface through laser annealing by irradiating a surface 100a or a back surface 100b of an object 100 with a laser beam L1, the object 100 including a functional element layer on a surface 100a side; and a second step of forming a modified layer inside the object 100 by irradiating the irradiation surface, which is flattened in the first step, with a laser beam L2. A pulse pitch of the laser beam L1 is shorter than a pulse pitch of the laser beam L2.

In the laser machining method according to the present embodiment, in a stage before irradiation is performed with the laser beam L2 for forming the modified layer inside the object 100, the irradiation surface for the laser beam L2 is irradiated with the laser beam L1 for flattening the irradiation surface through the laser annealing. In a case where the irradiation surface for the laser beam L2 when the modified layer is formed is rough and not flat, it may not be able to appropriately form the modified layer through the irradiation with the laser beam L2. In this regard, as in the laser machining method according to the present embodiment, by irradiating the irradiation surface when the modified layer is formed with the laser beam L1 for flattening the irradiation surface in advance (by performing laser annealing), the irradiation surface that is flattened can be irradiated with the laser beam L2, so that the modified layer can be appropriately formed inside the object 100. In addition, in the laser machining method according to the present embodiment, the pulse pitch of the laser beam L1 for the laser annealing is shorter than the pulse pitch of the laser beam L2 for forming the modified layer. In such a manner, by shortening the pulse pitch of the laser beam L1 for the laser annealing (shorter than the pulse pitch of the laser beam L2 for forming the modified layer), a region that is recrystallized and flattened after melting can be continuously formed, and the flattening of the irradiation surface through the laser annealing can be more appropriately realized. As described above, according to the laser machining method of the present embodiment, the irradiation surface of the object 100 can be appropriately flattened, and the modified layer can be appropriately formed inside the object 100.

In the laser machining method, the laser beam L1 and the laser beam L2 may be emitted from a common light source. According to such a configuration, the configuration related to laser machining can be simplified, and the downsizing of the device configuration can be realized.

In the laser machining method, a frequency of the laser beam L1 may be higher than a frequency of the laser beam L2. In the laser annealing, by performing irradiation with the next laser beam L1 before the irradiation region cools down after the irradiation with the laser beam L1, heat is accumulated and recrystallization is appropriately performed, so that the flattening of the irradiation surface can be realized. In this regard, by increasing the frequency of the laser beam L1 (for example, higher than the frequency of the laser beam L2), the flattening of the irradiation surface through the laser annealing can be more appropriately realized.

In the laser machining method, the number of branches of the laser beam L1 in a machining progress direction may be larger than the number of branches of the laser beam L2 in the machining progress direction. By increasing the number of branches of the laser beam L1 in the machining progress direction (for example, larger than the number of branches of the laser beam L2), the time required for the laser annealing process can be shortened.

In the laser machining method, the number of branches of the laser beam L1 in a direction intersecting a machining progress direction and parallel to the irradiation surface may be larger than the number of branches of the laser beam L2 in the direction intersecting the machining progress direction and parallel to the irradiation surface. Accordingly, the width flattened by the laser annealing process can be increased.

In the laser machining method, irradiation ranges of branched beams of the laser beam L1 may partially overlap each other on the irradiation surface. Accordingly, even when the energy per point is low, flattening can be performed. In addition, with the laser beam, unevenness occurs between the center of the beam and a location away from the center of the beam; however, by performing irradiation with the branched beams such that the irradiation ranges overlap each other, the above-described unevenness can be suppressed, and the irradiation surface can be more appropriately flattened.

In the laser machining method, the laser beam L1 may be a laser beam having a top-hat shape. Accordingly, a laser annealing region on the irradiation surface can be widened. In addition, the irradiation surface can be more flattened.

In the laser machining method, in the first step, the irradiation surface may be irradiated with the laser beam L1 such that the irradiation surface is flattened and the modified layer is formed inside the object 100. In such a manner, by also using the laser beam L1 for the laser annealing for flattening to form the modified layer, for example, the number of passes of the laser beam L2 for forming the modified layer is reduced, so that the time required for forming the modified layer can be shortened.

In the laser machining method, in the first step, the irradiation surface may be irradiated with the laser beam L1 such that the modified layer is not formed inside the object 100. Accordingly, a situation where a desired modified layer cannot be formed due to the unintended formation of a modified layer by the laser beam L1 for the laser annealing can be avoided.

In the laser machining method, in the first step, a condensing point of the laser beam L1 may be set to a position outside the object 100. Accordingly, the formation of the modified layer inside the object 100 by the laser beam L1 for the laser annealing can be appropriately avoided.

In the laser machining method, in the first step, the back surface 100b may be irradiated with the laser beam L1 using the back surface 100b as the irradiation surface, to flatten the back surface 100b. For example, the back surface 100b of the object 100 may be satin-finished or rough. When the back surface 100b of the object 100 is irradiated with the laser beam L2 for forming the modified layer, the laser beam L2 may be absorbed or scattered on the back surface 100b, so that the modified layer cannot be appropriately formed inside the object 100. In this regard, the back surface 100b is irradiated with the laser beam L1 for the laser annealing using the back surface 100b as the irradiation surface, to appropriately flatten the back surface 100b that is rough, so that the modified layer can be appropriately formed inside the object 100.

The laser machining method may further include a first grooving step of forming a weakened region 100y on the surface 100a by performing irradiation with a laser beam L3 from the back surface 100b of the object 100 before the second step. In the first step, the back surface 100b before the first grooving step may be irradiated with the laser beam L1 using the back surface 100b as the irradiation surface, to flatten the back surface 100b. After the weakened region 100y is formed on the surface 100a including the functional element layer in the first grooving step, by irradiating the back surface 100b with the laser beam L2 for forming the modified layer in the second step, a crack reaching the surface 100a side on which the functional element layer is formed can be appropriately formed using the weakened region 100y. Here, when the first grooving step is performed, if there is a damage to the back surface 100b on which the laser beam L3 is incident, it is difficult to appropriately perform grooving (IR grooving) on the surface 100a side, and the energy of the laser beam L3 for the grooving is limited. In this regard, by performing the first step for the laser annealing using the back surface 100b as the irradiation surface before the first grooving step, the first grooving step is performed in a state where the back surface 100b is flattened, so that the energy that can be input to the laser beam L3 in the first grooving step increases and the types of the objects 100 (devices) that can be handled increase. Accordingly, the grooving (IR grooving) can be more easily and appropriately performed on the surface 100a side.

The laser machining method may further include a second grooving step of removing a surface layer of the surface 100a of the object 100 by irradiating the surface 100a with a laser beam L4. In the first step, a bottom surface 100z of a groove formed on the surface 100a by the second grooving step may be irradiated with the laser beam L1 using the bottom surface 100z as the irradiation surface, to flatten the bottom surface 100z of the groove. After the surface layer of the surface 100a is removed in the second grooving step, by irradiating the surface 100a with the laser beam L2 for forming the modified layer in the second step, the machining throughput can be improved, and a reduction in machining quality, such as film peeling, can be suppressed. Here, after the second grooving step, the bottom surface 100z of the groove formed on the surface 100a by the grooving is roughened. For this reason, normally, stealth dicing machining cannot be performed from the surface 100a after the grooving, and a transfer is made to a back surface 100b side and irradiation is performed with the laser beam L2 for forming the modified layer from the back surface 100b side. In this case, the transfer cost increases, which is a problem. In this regard, after the second grooving step, by performing the first step for the laser annealing using the bottom surface 100z of the groove, which is formed on the surface 100a, as the irradiation surface, the bottom surface 100z of the groove formed on the surface 100a is flattened, so that stealth dicing machining can be performed from the surface 100a that is a grooving surface side, and the above-described transfer step is not required. Accordingly, a speeding up in machining and a reduction in cost can be realized.

### REFERENCE SIGNS LIST

1: laser machining device, 7: support unit, 9: control unit, 81, 82: light source, 100: object, 100a: surface, 100b: back surface, 100y: weakened region, 100z: bottom surface, L1: laser beam, L2: laser beam.

1: A laser machining method comprising:
a first step of flattening an irradiation surface through laser annealing by irradiating a surface or a back surface of an object with a first laser beam, the object including a functional element layer on a surface side; and
a second step of forming a modified layer inside the object by irradiating the irradiation surface, which is flattened in the first step, with a second laser beam,
a pulse pitch of the first laser beam is shorter than a pulse pitch of the second laser beam.

2: The laser machining method according to claim 1,
wherein the first laser beam and the second laser beam are emitted from a common light source.

3: The laser machining method according to claim 1,
wherein a frequency of the first laser beam is higher than a frequency of the second laser beam.

4: The laser machining method according to claim 1,
wherein the number of branches of the first laser beam in a machining progress direction is larger than the number of branches of the second laser beam in the machining progress direction.

5: The laser machining method according to claim 1,
wherein the number of branches of the first laser beam in a direction intersecting a machining progress direction and parallel to the irradiation surface is larger than the number of branches of the second laser beam in the direction intersecting the machining progress direction and parallel to the irradiation surface.

6: The laser machining method according to claim 4,
wherein irradiation ranges of branched beams of the first laser beam partially overlap each other on the irradiation surface.

7: The laser machining method according to claim 1,
wherein the first laser beam is a laser beam having a top-hat shape.

8: The laser machining method according to claim 1,
wherein in the first step, the irradiation surface is irradiated with the first laser beam such that the irradiation surface is flattened and the modified layer is formed inside the object.

9: The laser machining method according to claim 1,
wherein in the first step, the irradiation surface is irradiated with the first laser beam such that the modified layer is not formed inside the object.

10: The laser machining method according to claim 9,
wherein in the first step, a condensing point of the first laser beam is set to a position outside the object.

11: The laser machining method according to claim 1,
wherein in the first step, the back surface is irradiated with the first laser beam using the back surface as the irradiation surface, to flatten the back surface.

12: The laser machining method according to claim 11, further comprising:
a first grooving step of forming a weakened region on the surface by performing irradiation with a third laser beam from the back surface of the object before the second step,
wherein in the first step, the back surface before the first grooving step is irradiated with the first laser beam using the back surface as the irradiation surface, to flatten the back surface.

13: The laser machining method according to claim 1, further comprising:
a second grooving step of removing a surface layer of the surface of the object by irradiating the surface with a fourth laser beam,
wherein in the first step, a bottom surface of a groove formed on the surface by the second grooving step is irradiated with the first laser beam using the bottom surface as the irradiation surface, to flatten the bottom surface of the groove.

14: A laser machining device comprising:
a support unit configured to support an object including a functional element layer on a surface side;
an irradiation unit configured to irradiate the object with a laser beam; and
a control unit configured to perform a first control to control the irradiation unit such that a surface or a back surface of the object is irradiated with a first laser beam to flatten an irradiation surface through laser annealing, and a second control to control the irradiation unit such that the irradiation surface which is flattened is irradiated with a second laser beam having a longer pulse pitch than the first laser beam, to form a modified layer inside the object.

15: The laser machining device according to claim 14,
wherein in the first control, the control unit controls the irradiation unit such that the back surface is irradiated with the first laser beam using the back surface as the irradiation surface, to flatten the back surface.

16: The laser machining device according to claim 15,
wherein the control unit further performs a first grooving control to control the irradiation unit such that irradiation is performed with a third laser beam from the back surface of the object to form a weakened region on the surface, before performing the second control, and in the first control, controls the irradiation unit such that the back surface before the first grooving control is performed is irradiated with the first laser beam using the back surface as the irradiation surface, to flatten the back surface.

17: The laser machining device according to claim 14,
wherein the control unit further performs a second grooving control to control the irradiation unit such that the surface of the object is irradiated with a fourth laser beam to remove a surface layer of the surface, and in the first control, controls the irradiation unit such that a bottom surface of a groove formed on the surface by the second grooving control is irradiated with the first laser beam using the bottom surface as the irradiation surface, to flatten the bottom surface of the groove.
